(19) United States
(12) Patent Application Publication
(10) Pub. No.: US 2026/0302731 A1
(43) Pub. Date: Oct. 1, 2026

(54) QUANTUM CASCADE LASER DEVICE AND METHOD FOR MANUFACTURING QUANTUM CASCADE LASER DEVICE

(71) Applicant: Mitsubishi Electric Corporation, Tokyo (JP)

(72) Inventor: Kimio SHIGIHARA, Tokyo (JP)

(73) Assignee: Mitsubishi Electric Corporation, Tokyo (JP)

(21) Appl. No.: 19/489,383

(22) PCT Filed: Jul. 12, 2023
(86) PCT No.: PCT/JP2023/025763

§ 371 Date: Dec. 2, 2025

(51) Int. Cl. H01S 5/34; H01S 5/024; H01S 5/343

(52) U.S. Cl. CPC H01S 5/3402; H01S 5/3438; H01S 5/024; H01S 2302/02

(57) ABSTRACT

A quantum cascade laser device of the present disclosure includes a core region comprising a plurality of stages each having an active region and an injector region, wherein a gain has a maximum gain at λ_{qcl} when current is injected, and a low-reflectivity film is provided on one end surface such that the reflectivity is minimized at λ_{cot} configured to be separated from λ_{qcl} by a predetermined wavelength within the wavelength range between two points in which the gain decreases by a predetermined ratio of the maximum gain where Δλ_{qcl} is defined as a wavelength width between the two points, and Δλₘᵢᵣ between two points where the mirror loss is generated by subtracting a predetermined loss from the maximum mirror loss is set such that Δλₘᵢᵣ is smaller than Δλ_{qcl}.

### TECHNICAL FIELD

The present disclosure relates to a quantum cascade laser device and a method for manufacturing a quantum cascade laser device.

### BACKGROUND ART

Conventional terahertz nonlinear quantum cascade laser devices nonlinear quantum (Terahertz cascade laser: THz-nonlinear-QCL, hereafter referred to as THz nonlinear QCL device) are designed such that two radiative transitions are generated in a single device, as described, for example, in Non-Patent Document 1. Accordingly, it is possible to oscillate at two different frequencies ω₁ and ω₂, thereby differential frequencies ω₁-ω₂ are output by utilizing the nonlinear optical effect of InP or GaAs crystal.

### CITATION LIST

### Non-Patent Document

Non-Patent Document 1: K. Fujita et al., “Recent progress in terahertz difference-frequency quantum cascade laser sources,” Nanophotonics, vol. 7, No. 11, pp. 1795-1817 September 2018
Non-Patent Document 2: J. Kim et al., “Theoretical and experimental study of optical gain and linewidth enhancement factor of type-I quantum-cascade lasers,” IEEE J. Quantum. Electron., vol. 40, No. 12, pp. 1663-1674 December 2004
Non-Patent Document 3: I. Ladany et al., “Al2O3 half-wave films for long-life cw lasers,” Appl. Phys. Lett., vol. 30, No. 2, pp. 87-88, 1977
Non-Patent Document 4: K. Fujita et al., “High-performance, homogeneous broad-gain quantum cascade lasers based on dual-upper-state,” Appl. Phys. Lett., vol. 96, 241107, 2010
Non-Patent Document 5: K. Fujita et al., “Broad gain (Δλ/λ0^{~}0.4), temperature-insensitive (T0^{~}510K) quantum cascade lasers,” Opt. Express, vol. 19, no. 3, pp. 2694-2701, 2011

### SUMMARY OF THE INVENTION

### Problem to be Solved by the Invention

In conventional THz nonlinear QCL devices, a quantum well structure must be designed such that two radiative transitions are generated in a single device, and the laser output from these two radiative transitions must be made approximately equal, which makes design extremely difficult. Furthermore, in order to stably oscillate two different frequencies ω₁ and ω₂, it is necessary to precisely control thicknesses and compositions of well layers and barrier layers constituting the quantum well structure.

The present disclosure has been made to solve the above-mentioned problems, and an object of the present disclosure is to provide a quantum cascade laser device capable of easily achieving terahertz oscillation and a method for manufacturing the quantum cascade laser device.

### Means to Solve the Problem

A quantum cascade laser device according to the present disclosure includes: a semiconductor substrate; a first-conductivity-type first cladding layer formed above the semiconductor substrate; a core region formed above the first cladding layer and comprising a plurality of stages each having an active region in which a plurality of barrier layers and a plurality of well layers are formed alternately, and an injector region configured to inject electrons into the active region; and a first-conductivity-type second cladding layer formed above the core region, wherein a cavity length is L, and a gain has a maximum gain value at a wavelength λ_{qcl} when current is injected, and a low-reflectivity film is provided on one end surface such that the reflectivity is minimized at a wavelength λ_{cot} configured to be separated from the wavelength λ_{qcl} by a predetermined wavelength where a wavelength width Δλ_{qcl} is defined as a wavelength width between two points in which the gain value decreases by a predetermined ratio of the maximum gain value, and a wavelength width Δλₘᵢᵣ between two points where the mirror loss value is generated by subtracting a predetermined loss value from the maximum mirror loss value calculated from the reflectivity Rr of the other end surface and the cavity length L is set such that the wavelength width Δλₘᵢᵣ is smaller than the wavelength width Δλ_{qcl}.

A method for manufacturing above-mentioned quantum cascade laser device according to the present disclosure, the method comprising steps of: cleaving a wafer after completing a wafer process to form cleavage bars; obtaining the wavelength corresponding to the maximum gain value and the gain band by driving the cleavage bar and measuring the wavelength dependence of the gain of the quantum cascade laser device; designing a low-reflectivity film having a minimum reflectivity at a wavelength separated by a predetermined wavelength from the wavelength corresponding to the maximum gain value; and depositing the low-reflectivity film on a front-end surface of the quantum cascade laser device.

### Effect of the Invention

In the quantum cascade laser device and the method for manufacturing the quantum cascade laser device according to the present disclosure, a low-reflectivity film optimally designed for generating terahertz light is formed on the front-end surface of the quantum cascade laser device, thus providing an effect that a quantum cascade laser device capable of easily outputting terahertz light can be obtained, and the quantum cascade laser device can be easily manufactured.

### BRIEF DESCRIPTION OF THE DRAWINGS

FIG. 1 is an overview of a quantum cascade laser device according to Embodiment 1;

FIG. 2 is a cross-sectional view of the quantum cascade laser device along the yₐ-y_{b} line in FIG. 1 according to Embodiment 1;

FIG. 3 is a schematic diagram showing a band structure of a conduction band of one stage when an electric field is applied in the quantum cascade laser device according to Embodiment 1;

FIG. 4 is a schematic diagram showing a quantum well structure of one stage and the square of a wave function at each energy level in the quantum cascade laser device according to Embodiment 1;

FIG. 5 is a diagram showing an example of the wavelength dependence of the gain in the quantum cascade laser device according to Embodiment 1;

FIG. 6 is a schematic diagram showing a case where a single-layer coating film is replaced with a three-layer coating film in the quantum cascade laser device according to Embodiment 1;

FIG. 7 is a schematic diagram showing a coating film configuration when a coating film is inserted between the end surface and a first-layer coating film in the quantum cascade laser device according to Embodiment 1;

FIG. 8 is a diagram showing the wavelength dependence of the reflectivity of the coating film of the quantum cascade laser device according to Embodiment 1;

FIG. 9 is a schematic diagram for explaining a method for designing a low-reflectivity film having a minimum reflectivity for the quantum cascade laser device according to Embodiment 1;

FIG. 10 is a diagram showing the wavelength dependence of the reflectivity and the wavelength dependence of the mirror loss of the coating film provided on the end surface in the quantum cascade laser device according to Embodiment 1;

FIG. 11 is a diagram showing the wavelength dependence of the gain and the wavelength dependence of the total loss in the quantum cascade laser device according to Embodiment 1;

FIG. 12 is a cross-sectional view of the quantum cascade laser device along the xₐ-x_{b} line in FIG. 1 according to Embodiment 1;

FIG. 13 is a cross-sectional view of a quantum cascade laser device according to Embodiment 2;

FIG. 14 is a schematic diagram showing a quantum well structure of one stage and the square of a wave function at each energy level in a quantum cascade laser device according to Embodiment 3;

FIG. 15 is a schematic diagram showing a quantum well structure of one stage and the square of a wave function at each energy level in a quantum cascade laser device according to Embodiment 4;

FIG. 16 is a schematic diagram showing a coating film configuration when a coating film is inserted between the end surface and a first-layer coating film, and another coating film is further provided on a third-layer coating film in a quantum cascade laser device according to Embodiment 5;

FIG. 17 is a diagram showing the wavelength dependence of the reflectivity of the coating film provided on the front-end surface of the quantum cascade laser device according to Embodiment 5;

FIG. 18 is a schematic diagram for explaining a method for designing a low-reflectivity film having a minimum reflectivity for the quantum cascade laser device according to Embodiment 5;

FIG. 19 is a diagram comparing the wavelength dependence of the reflectivity and the wavelength dependence of the mirror loss of the coating film provided on the front-end surface of the quantum cascade laser device according to Embodiment 5 with those of Embodiment 1;

FIG. 20 is a schematic diagram for explaining the method for designing a low-reflectivity film having a minimum reflectivity for the quantum cascade laser device according to Embodiments 1 and 5;

FIG. 21 is a diagram showing the wavelength dependence of the reflectivity of a low-reflectivity film designed by the method for designing a low-reflectivity film having a minimum reflectivity for the quantum cascade laser device according to Embodiments 1 and 5;

FIG. 22 is a schematic diagram for explaining the method for designing a low-reflectivity film having a minimum reflectivity for the quantum cascade laser device according to Embodiments 1 and 5;

FIG. 23 is a schematic diagram for explaining the method for designing a low-reflectivity film having a minimum reflectivity for the quantum cascade laser device according to Embodiments 1 and 5;

FIG. 24 is a diagram showing the wavelength dependence of the reflectivity of a low-reflectivity film designed by the method for designing a low-reflectivity film having a minimum reflectivity for the quantum cascade laser device according to Embodiments 1 and 5;

FIG. 25 is a schematic diagram for explaining the method for designing a low-reflectivity film having a minimum reflectivity for the quantum cascade laser device according to Embodiments 1 and 5;

FIG. 26 is a diagram showing the wavelength dependence of the reflectivity of a low-reflectivity film designed by the method for designing a low-reflectivity film having a minimum reflectivity for the quantum cascade laser device according to Embodiments 1 and 5;

FIG. 27 is a schematic diagram for explaining the method for designing a low-reflectivity film having a minimum reflectivity for a quantum cascade laser device according to Embodiments 1 and 5;

FIG. 28 is a diagram showing the wavelength dependence of the reflectivity of a low-reflectivity film designed by the method for designing a low-reflectivity film having a minimum reflectivity for the quantum cascade laser device according to Embodiments 1 and 5;

FIG. 29 is an overview of a quantum cascade laser device according to Embodiments 6;

FIG. 30 is a cross-sectional view of the quantum cascade laser device along the yₐ-y_{b} line in FIG. 29 according to Embodiments 6;

FIG. 31 is an overview of a quantum cascade laser device according to Embodiments 7;

FIG. 32 is a cross-sectional view of the quantum cascade laser device along the yₐ-y_{b} line in FIG. 31 according to Embodiments 7;

FIG. 33A shows one step of a method for manufacturing a quantum cascade laser device according to Embodiments 1 to 7;

FIG. 33B shows one step of the method for manufacturing a quantum cascade laser device according to Embodiments 1 to 7;

FIG. 33C is a diagram showing one step of the method for manufacturing a quantum cascade laser device according to Embodiments 1 to 7;

FIG. 33D is a diagram showing one step of the method for manufacturing a quantum cascade laser device according to Embodiments 1 to 7;

FIG. 33E is a diagram showing one step of the method for manufacturing a quantum cascade laser device according to Embodiments 1 to 7;

FIG. 33F is a diagram showing one step of the method for manufacturing a quantum cascade laser device according to Embodiments 1 to 7;

FIG. 33G is a diagram showing one step of the method for manufacturing a quantum cascade laser device according to Embodiments 1 to 7;

FIG. 33H is a diagram showing one step of the method for manufacturing a quantum cascade laser device according to Embodiments 1 to 7.

### DESCRIPTION OF EMBODIMENTS

### Embodiment 1

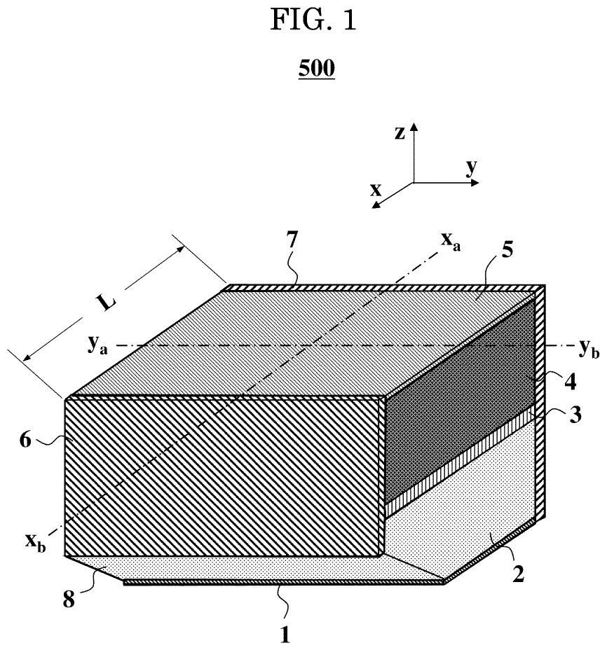

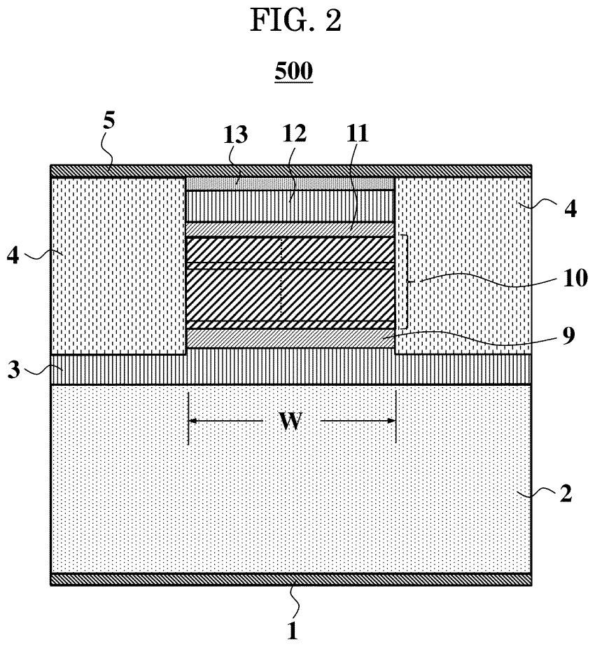

FIG. 1 is an overview of a quantum cascade laser device 500 according to Embodiment 1. FIG. 2 is a cross-sectional view of the quantum cascade laser device 500 along the line yₐ-y_{b} in FIG. 1 according to Embodiment 1. The cavity length of the quantum cascade laser device 500 is L and the ridge width thereof is W. The quantum cascade laser device 500 has a buried ridge-type waveguide structure.

As shown in FIGS. 1 and 2, the quantum cascade laser device 500 includes: an n-type first electrode 1; an n-type InP substrate 2; an n-type InP first cladding layer 3; an Fe-doped InP current blocking layer 4; an n-type second electrode 5; a front-end-surface coating film 6; a rear-end-surface coating film 7; a terahertz light extraction surface 8; an n-type Ga_{0.47}In_{0.53}As (hereinafter referred to as GaInAs) first optical confinement layer (n-type GaInAs first optical confinement layer 9); a core region 10; an n-type GaInAs second optical confinement layer 11; an n-type InP second cladding layer 12; an n-type GaInAs contact layer 13; and an n-type second electrode 5. Note that the n-type conductivity is also referred to as the first conductivity type.

As shown in the cross-sectional view of FIG. 2, the quantum cascade laser device 500 comprises: the n-type GaInAs first optical confinement layer 9; the core region 10 having a stacked structure (35 stages) of 35 stages 40 each composed of an active region 38 and an injector region 39; the n-type GaInAs second optical confinement layer 11; the n-type InP second cladding layer 12; the n-type GaInAs contact layer 13; and the n-type second electrode 5.

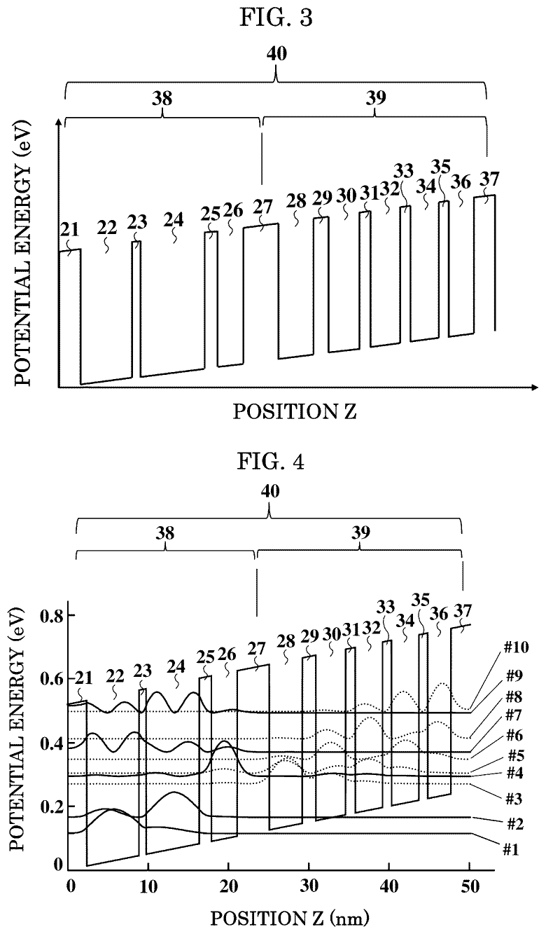

FIG. 3 is a schematic diagram showing a band structure of a conduction band of one stage 40 when an electric field of 5.0×10⁶ V/m is applied from the n-type second electrode 5 to the n-type first electrode 1 in the quantum cascade laser device 500 according to Embodiment 1. Such a band structure is disclosed, for example, in Non-Patent Document 2. As shown in FIG. 3, the stage 40 is composed of the active region 38 and the injector region 39.

The active region 38 comprises: an undoped Al_{0.48}In_{0.52}As (hereinafter referred to as AlInAs) barrier layer (undoped AlInAs barrier layer 21) having a thickness of 2.4 nm; an undoped GaInAs well layer 22 having a thickness of 6.5 nm; an undoped AlInAs barrier layer 23 having a thickness of 0.9 nm; an undoped GaInAs well layer 24 having a thickness of 6.6 nm; an undoped AlInAs barrier layer 25 having a thickness of 1.5 nm; an undoped GaInAs well layer 26 having a thickness of 3.2 nm; and a part of an undoped AlInAs barrier layer 27 having a thickness of 4.0 nm.

The injector region 39 comprises: a remaining part of the undoped AlInAs barrier layer 27 having a thickness of 4.0 nm; an undoped GaInAs well layer 28 having a thickness of 4.1 nm; an undoped AlInAs barrier layer 29 having a thickness of 1.7 nm; an undoped GaInAs well layer 30 having a thickness of 3.7 nm; an undoped AlInAs barrier layer 31 having a thickness of 1.2 nm; an n-type GaInAs well layer 32 having a thickness of 3.4 nm and doped to be n-type; an n-type AlInAs barrier layer 33 having a thickness of 1.1 nm and doped to be n-type; an n-type GaInAs well layer 34 having a thickness of 3.4 nm and doped to be n-type; an undoped AlInAs barrier layer 35 having a thickness of 1.1 nm; an undoped GaInAs well layer 36 having a thickness of 2.9 nm; and an undoped AlInAs barrier layer 37 having a thickness of 2.4 nm.

The active region 38 is a region in which electrons transition between sub-bands formed within the active region 38 and then emit light. The injector region 39 is a region in which electrons are injected into the active region 38. In Embodiment 1, the case in which the total number of well layers constituting the active region 38 is three, that is, the case in which there are three GaInAs well layers 22, 24, and 26 is exemplified as an example. In Embodiment 1, the doping concentration of the n-type GaInAs well layer 32, the n-type AlInAs barrier layer 33, and the n-type GaInAs well layer 34 in the injector region 39 is, as an example, 2.5×10¹⁷ cm⁻³.

As shown in FIG. 2, in Embodiment 1, the total number of stages 40 is set to 35. Since 35 identical stages are connected continuously, it is sufficient to analyze the laser characteristics in one stage 40.

FIG. 4 is a schematic diagram showing a quantum well structure of one stage and the square of a wave function at each energy level in the quantum cascade laser device according to Embodiment 1. That is, FIG. 4 shows whether the probability of electron existence is high or low.

There are a total of ten energy levels allowed in one stage 40. The energy levels where electrons exist mainly in the active region 38 are shown as solid lines. The energy levels where electrons exist mainly in the injector region 39 are shown as dashed lines. The five energy levels in which electrons mainly exist in the active region 38 are an energy level #1, an energy level #2, an energy level #4, an energy level #7, and an energy level #9. The five energy levels in which electrons mainly exist in the injector region 39 are an energy level #3, an energy level #5, an energy level #6, an energy level #8, and an energy level #10.

Calculating the electron density within the stage 40, it can be seen that among the energy levels where electrons mainly exist in active region 38, the electron density at the energy level #4 is higher than the electron density at the energy level #2, and thus the inversion distribution necessary for laser oscillation is formed.

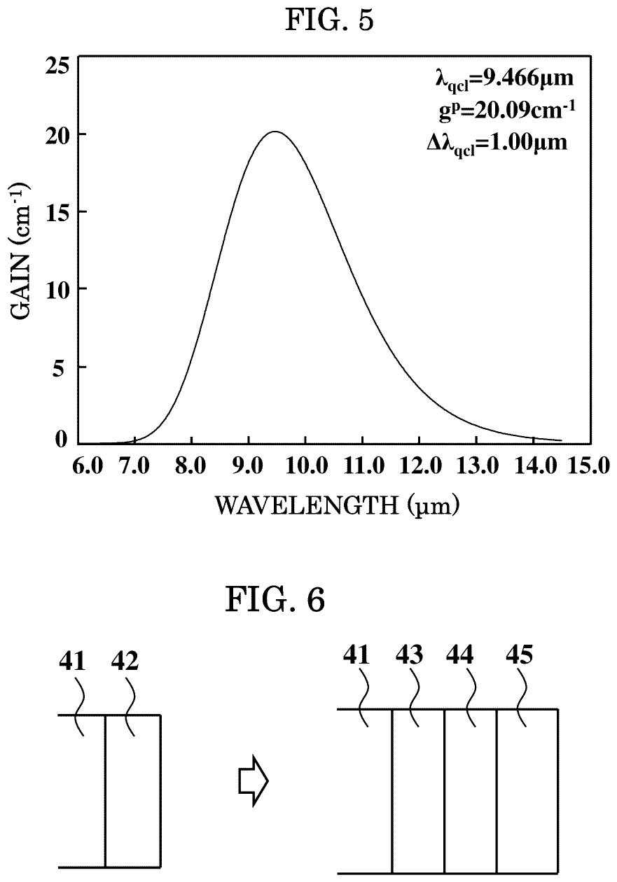

FIG. 5 shows an example of the wavelength dependence of the gain in the quantum cascade laser device 500 according to Embodiment 1. FIG. 5 shows the wavelength dependence of the gain when an electric field is applied from the n-type second electrode 5 to the n-type first electrode 1 and a current is injected 137 mA in the quantum cascade laser device 500 having a cavity length L of 1.36 mm and a ridge width W of 14 μm. At a wavelength (λ_{qcl}) of 9.466 μm, the maximum gain value g^{p} of 20.09 cm⁻¹ is obtained. Furthermore, the full wavelength width Δλ_{qcl} between the gain values at two points, which occurs when the gain value decreases by 10% from the maximum gain value gr, is calculated to be 1.00 μm.

Next, the loss of the quantum cascade laser device 500 will be considered. The total loss αₜ of the quantum cascade laser device 500 can be expressed as the sum of a loss (α_{wc}), which is almost independent of wavelength such as waveguide loss or carrier absorption, and a mirror loss (αₘᵢᵣ), as shown in the following Expressions (1) and (2).

$$[ Mathematical 1 ]$$

$${α}_{t} = {α}_{mir} + {α}_{wc} \qquad ( 1 )$$

$${α}_{mir} = \frac{1}{2 L} LN ( \frac{1}{{R}_{f} {R}_{r}} ) \qquad ( 2 )$$

In Expression (2), R_{f}, Rᵣ and L are the front-end-surface reflectivity, the rear-end-surface reflectivity and the cavity length, respectively. In Embodiment 1, the front-end-surface reflectivity R_{f} is designed as described below by assuming that the front-end-surface reflectivity R_{f} has the wavelength dependence. On the other hand, the rear-end-surface reflectivity Rᵣ achieves almost 100% reflectivity by coating the rear-end surface with gold (Au) or the like, and does not depend on the wavelength.

Furthermore, assuming α_{wc} to be 5 cm⁻¹ and considering the asymmetry of the gain distribution, it is estimated that when the total loss αₜ is maximum in the vicinity of wavelength λ_{cot}=9.461 μm, that is, approximately 24.79 cm⁻¹, and the loss band is narrower than the gain band, oscillation at two wavelengths is possible. In this case, the reflectivity is 0.459% at the wavelength λ_{cot}=9.461 μm, which corresponds to 19.79 cm⁻¹ that is the maximum value of the mirror loss αₘᵢᵣ.

Accordingly, the desired minimum reflectivity R₀=0.459% will be achieved at the desired wavelength λ_{cot}=9.461 μm. The desired wavelength λ_{cot} and the desired minimum reflectivity R₀ are suitably changed according to the maximum gain value g^{p}, the wavelength λ_{qcl} to be the maximum gain value, and the gain band of the quantum cascade laser device. The design method will be described later.

As disclosed in Non-Patent Document 3, when a single-layer coating film made of Al₂O₃ having a refractive index n_{f} of 1.72 is provided in a quantum cascade laser device having a refractive index n_{c} (3.6, GaAs) at the wavelength λ_{cot}, the reflectivity changes periodically with respect to the thickness of the coating film, and has a minimum value when the thickness d_{f} thereof is an integer multiple of λ_{cot}/(4n_{f}). The minimum reflectivity R₀ in this case is expressed by the following Expression (3), and is uniquely determined.

$$[ Mathematical 2 ]$$

$${R}_{0} = {( \frac{{n}_{c} - {n}_{f}^{2}}{{n}_{c} + {n}_{f}^{2}} )}^{2} \qquad ( 3 )$$

Conversely, from Expression (3), the refractive index n_{fl} and the refractive index n_{fh} of the coating film to achieve the desired minimum reflectivity R₀ are calculated from the following Expression (4).

$$[ Mathematical 3 ]$$

$${n}_{fl} = {( \frac{1 - \sqrt{{R}_{0}}}{1 + \sqrt{{R}_{0}}} )}^{\frac{1}{2}} \sqrt{{n}_{c}} \qquad ( 4 )$$

$${n}_{fh} = {( \frac{1 + \sqrt{{R}_{0}}}{1 - \sqrt{{R}_{0}}} )}^{\frac{1}{2}} \sqrt{{n}_{c}}$$

The same applies to the quantum cascade laser device. As is clear from Expression (4), it is necessary to change the refractive index (n_{fl}, n_{fh}) to obtain the desired minimum reflectivity R₀ by using a single-layer coating film. However, in the mid-infrared wavelength range, which is the oscillation wavelength range of quantum cascade laser devices, no materials with the required refractive index and substantially no absorption have been found to the present.

Accordingly, an attempt is made to replace the single-layer coating film with a multi-layer coating film composed of multiple materials that do not absorb light in the mid-infrared range, thereby achieving the minimum reflectivity R₀.

Since the same can be applied to the case of n_{fh} with a higher refractive index, n_{f} with a lower refractive index is used for explanation in Embodiment 1. When the effective refractive index n_{c} of the quantum cascade laser device 500 is 3.2 and the desired minimum reflectivity R₀ by using the single-layer coating film is R₀=0.00459 (0.459%), the refractive index n_{f} is calculated as 1.67150083 from Expression (4).

Consider the replacement of the single-layer coating film by a three-layer coating film made of three materials with known refractive indices, wherein at least one material has a refractive index lower than the refractive index n_{f} and at least one other material has a refractive index higher than the refractive index n_{fl}.

FIG. 6 is a schematic diagram of a case where a single-layer coating film 42 having the refractive index n_{fl} and a thickness d_{fl} of λ_{cot}/(4n_{fl}) is replaced by a three-layer coating film having a refractive index n₁ and a thickness d₁, a refractive index n₂ and a thickness d₂, and the refractive index n₁ and a thickness d₃, respectively. As shown in FIG. 6, the single-layer coating film 42 having the refractive index n_{fl} (=1.67150083) and a thickness d_{fl}=λ_{cot}/(4n+1) formed on the end surface of the quantum cascade laser device 41 having an effective refractive index n_{c} of 3.2 is replaced by a three-layer coating film composed of a first coating film 43 having the refractive index n₁ and the thickness d₁, a second coating film 44 having the refractive index n₂ and the thickness d₂, and a third coating film 45 having the refractive index n₁ and the thickness d₃. Assuming that the single-layer coating film 42 can be replaced by the three-layer coating film, the characteristic matrices of both are equal, as expressed by the following Expression (5).

$$[ Mathematical 4 ]$$

$$( \begin{matrix}0 & \frac{- i}{{n}_{fl}} \\ - i {n}_{fl} & 0\end{matrix} ) = ( \begin{matrix}cos {ϕ}_{1} & \frac{- i}{{n}_{1}} sin {ϕ}_{1} \\ - i {n}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - i {n}_{2} sin {ϕ}_{2} & cos {ϕ}_{2}\end{matrix} ) ( \begin{matrix}cos {ϕ}_{3} & \frac{- i}{{n}_{3}} sin {ϕ}_{3} \\ - i {n}_{3} sin {ϕ}_{3} & cos {ϕ}_{3}\end{matrix} ) \qquad ( 5 )$$

The phase terms Φ₁, Φ₂, and Φ₃ of each coating film in Expression (5) are represented by the following Expression (6).

$$[ Mathematical 5 ]$$

$${ϕ}_{1} = 2 π {n}_{1} {d}_{1} / {λ}_{cot} , {ϕ}_{2} = 2 π {n}_{2} {d}_{2} / {λ}_{cot} , {ϕ}_{3} = 2 π {n}_{3} {d}_{3} / {λ}_{cot} \qquad ( 6 )$$

In Expression (5), since the refractive index n₁ and the refractive index n₂ are known, the unknowns are three thicknesses d₁, de, and d₃, and each thickness can be calculated by solving Expression (5).

Solving Expression (5), for example, at the wavelength of λ_{cot}=9.461 μm, YF₃ having the refractive index n₁=1.40 lower than the refractive index n_{f} for the first coating film 43, ZnSe having the refractive index n₂=2.41 higher than the refractive index n_{f} for the second coating film 44, and CeF₃ having the refractive index n₁=1.45 lower than the refractive index n_{f} for the third coating film 45, the thickness of each coating film is d₁=609.328 nm, d₂=183.785 nm, and d₃=697.248 nm, respectively. In order to narrow the reflectivity band, a coating film 46 having a refractive index nₐ and a thickness dₐ of λ_{cot}/(2nₐ) may be inserted between the end surface of the quantum cascade laser device 41 and the first coating film 43.

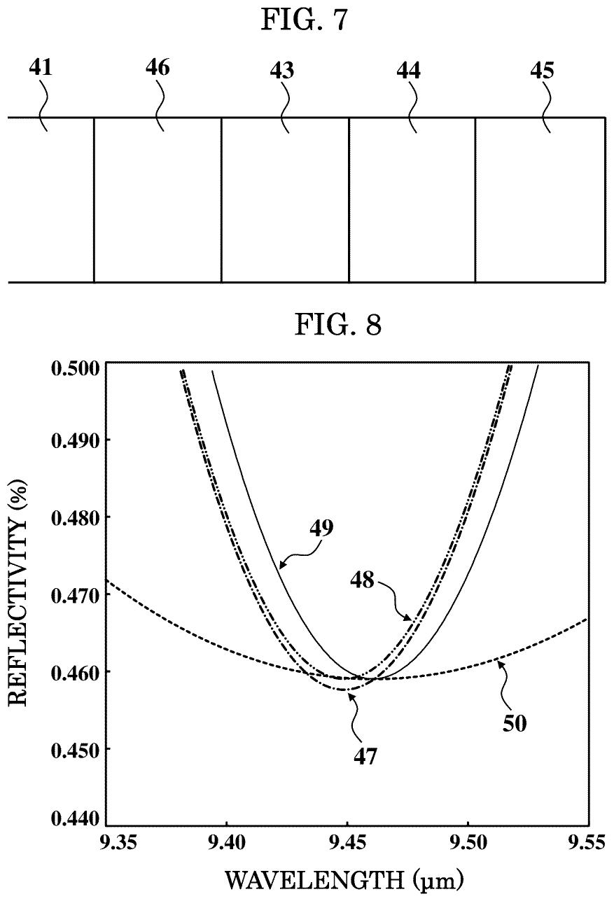

FIG. 7 is a schematic diagram showing the coating film configuration of a four-layer coating film according to Embodiment 1. In FIG. 7, the coating film 46 has the refractive index nₐ and the thickness dₐ of λ_{cot}/(2nₐ). The characteristic matrix of the four-layer coating film is represented by the following Expression (7).

$$[ Mathematical 6 ]$$

$$( \begin{matrix}{m}_{11} & {m}_{12} \\ {m}_{21} & {m}_{22}\end{matrix} ) = ( \begin{matrix}cos {ϕ}_{a} & \frac{- i}{{n}_{a}} sin {ϕ}_{a} \\ - i {n}_{a} sin {ϕ}_{a} & cos {ϕ}_{a}\end{matrix} ) ( \begin{matrix}cos {ϕ}_{1} & \frac{- i}{{n}_{1}} sin {ϕ}_{1} \\ - i {n}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - i {n}_{2} sin {ϕ}_{2} & cos {ϕ}_{2}\end{matrix} ) ( \begin{matrix}cos {ϕ}_{3} & \frac{- i}{{n}_{3}} sin {ϕ}_{3} \\ - i {n}_{3} sin {ϕ}_{3} & cos {ϕ}_{3}\end{matrix} ) \qquad ( 7 )$$

In Expression (7), the phase terms Φₐ, Φ₁, Φ₂ and Φ₃ of each coating film are expressed by the following Expression (8), and the thickness dₐ of the inserted coating film 46 is expressed by the following Expression (9).

$$[ Mathematical 7 ]$$

$${ϕ}_{a} = 2 π {n}_{a} {d}_{a} / {λ}_{cot} , {ϕ}_{1} = 2 π {n}_{1} {d}_{1} / {λ}_{cot} , \qquad ( 8 )$$

$${ϕ}_{2} = 2 π {n}_{2} {d}_{2} / {λ}_{cot} , {ϕ}_{3} = 2 π {n}_{3} {d}_{3} / {λ}_{cot}$$

$${d}_{a} = {λ}_{cot} / ( 2 {n}_{a} ) \qquad ( 9 )$$

The reflectivity of the coating film is expressed by the following Expression (10) using matrix components m₁₁, m₁₂, m₂₁ and m₂₂.

$$[ Mathematical 8 ]$$

$$R = {\vert r \vert}^{2} = {\vert \frac{( {m}_{11} + {m}_{12} ) {n}_{c} - ( {m}_{21} + {m}_{22} )}{( {m}_{11} + {m}_{12} ) {n}_{c} + ( {m}_{21} + {m}_{22} )} \vert}^{2} \qquad ( 10 )$$

As an example of the material of the inserted coating film 46, assume CeO₂ having the refractive index nₐ of 1.70. The thickness of the coating film 46 is dₐ=λ_{cot}/(2nₐ)=2782.60 nm at a wavelength λ_{cot}=9.461 μm. In the quantum cascade laser device having the three-layer coating film each having the thickness of d₁=609.328 nm, d₂=183.785 nm and d₃=697.248 nm, the wavelength dependence of the reflectivity when the coating film 46 is inserted between the end surface of the quantum cascade laser device 41 and the first coating film 43 is as shown by the dash-dotted line 47 in FIG. 8. At the wavelength λₘᵢₙ=9.449 μm, the minimum reflectivity value Rₘᵢₙ⁰ of the four-layer coating film is 0.4576%.

In the present disclosure, the meanings of Rₘᵢₙ and Rₘᵢₙ⁰ are as follows.
(1) Rₘᵢₙ: The minimum reflectivity value of the multi-layer coating film in the case where the single-layer coating film with the setting reflectivity R₁ is replaced by the multi-layer coating film.
(2) Rₘᵢₙ⁰: The minimum reflectivity value of the multi-layer coating film in the case where the single-layer coating film with the desired minimum reflectivity R₀ is replaced by the multi-layer coating film.

While the desired minimum reflectivity R₀ of the single-layer coating film is 0.459%, the minimum reflectivity value Rₘᵢₙ⁰ of the four-layer coating film is 0.4576%, which is lower than the minimum reflectivity R₀ of the single-layer coating film. Thus, the setting reflectivity R₁ is set as high as 0.46038% so as to achieve the desired minimum reflectivity R₀ for the minimum reflectivity value Rₘᵢₙ of the four-layer coating film. The standard for the reflectivity increment ΔR₀ is R₀−Rₘᵢₙ⁰=0.0014%, and the reflectivity increment ΔR₀ is adjusted until the setting reflectivity R₁ matches the desired minimum reflectivity R₀. In Embodiment 1, the reflectivity increment ΔR₀ is 0.00139%.

$$[ Mathematical 9 ]$$

$${n}_{fl}^{1} = {( \frac{1 - \sqrt{{R}_{1}}}{1 + \sqrt{{R}_{1}}} )}^{\frac{1}{2}} \sqrt{{n}_{c}} \qquad ( 11 )$$

The refractive index n_{fl}¹ of the single-layer coating film 42 to achieve R₁=0.460388% is calculated to be 1.67132893 from Expression (11).

$$\begin{matrix}[ Mathematical 10 ] & \\ ( \begin{matrix}0 & \frac{- i}{{n}_{fl}^{1}} \\ - i {n}_{fl}^{1} & 0\end{matrix} ) = ( \begin{matrix}cos {ϕ}_{1} & \frac{- i}{{n}_{1}} sin {ϕ}_{1} \\ - i {n}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - i {n}_{2} sin {ϕ}_{2} & cos {ϕ}_{2}\end{matrix} ) ( \begin{matrix}cos {ϕ}_{3} & \frac{- i}{{n}_{1}} sin {ϕ}_{3} \\ - i {n}_{1} sin {ϕ}_{3} & cos {ϕ}_{3}\end{matrix} ) & ( 12 )\end{matrix}$$

Solving Expression (12), the thickness of each coating film is calculated to be d₁=609.407 nm, d₂=183.660 nm, and d₃=697.402 nm respectively. The wavelength dependence of the reflectivity when the coating film 46 having the refractive index nₐ of 1.70 and the thickness dₐ of 2782.60 nm is inserted between the end surface of the quantum cascade laser device 41 and the first coating film 43 is shown as a double-dash line 48 in FIG. 8. The minimum reflectivity value Rₘᵢₙ of the three-layer coating film is 0.459% at the wavelength λₘᵢₙ=9.449 μm, and the desired minimum reflectivity of 0.459% can be achieved.

Next, when the thickness of each coating film is multiplied by λ_{cot}/λₘᵢₙ, the thickness of each coating film is calculated to be dₐ=2786.1338 nm, dₗ=610.1809 nm, d₂=183.8932 nm, and d₃=698.2877 nm, respectively. The wavelength dependence of the reflectivity in this case is shown by the solid line 49 in FIG. 8. It can be seen that the minimum reflectivity R₀ is 0.459% at the wavelength λ_{cot}=9.461 μm. For reference, the wavelength dependence of the reflectivity of a single-layer coating film having a refractive index n_{fl} (=1.67150083) and a thickness d_{fl} is shown as the dashed line 50 in FIG. 8.

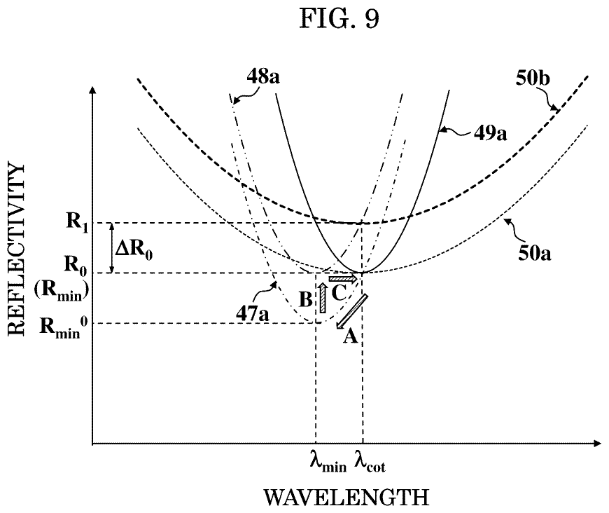

The above method for replacement will be described with reference to FIG. 9.
(1) In order to replace the desired minimum reflectivity (R₀) of the single-layer coating film (the wavelength dependence of the reflectivity is dashed line 50a) with the three-layer coating film, the thickness of each coating film of the three-layer coating film is determined such that the characteristic matrices of both coating films are equal. Next, the wavelength dependence of the reflectivity of the four-layer coating film in which the coating film 46 having the refractive index nₐ and the thickness dₐ of λ_{cot}/(2nₐ) is inserted is calculated. Since the coating film 46 having the refractive index nₐ and the thickness dₐ of λ_{cot}/(2nₐ) has no effect on the reflectivity at the wavelength the minimum reflectivity at the wavelength λ_{cot} is R₀, but, the minimum reflectivity value of the four-layer coating film (the minimum reflectivity value Rₘᵢₙ⁰ of the four-layer coating film) and the wavelength (λₘᵢₙ) at which the minimum reflectivity is achieved are shifted. The wavelength dependence of the reflectivity in this case is represented by the dash-dot line 47a in FIG. 9.
(2) Setting that the setting reflectivity R₁ of the single-layer coating film is R₁=R₀+ΔR₀ (the wavelength dependence of the reflectivity is represented by the dashed line 50b), calculate the thickness of each coating film of the three-layer coating film such that the characteristic matrices of both coating films are equal, and then, the wavelength dependence of the reflectivity of the four-layer coating film in which the coating film 46 having the refractive index nₐ and the thickness dₐ of λ_{cot}/(2nₐ) is inserted is calculated. Then, set the minimum reflectivity at the wavelength λₘᵢₙ such that the minimum reflectivity value Rₘᵢₙ is equal to the desired minimum reflectivity R₀. The wavelength dependence of the reflectivity in this case is represented by the double-dash line 48a in FIG. 9.
(3) The thickness of each coating film of the four-layer coating film is multiplied by λ_{cot}/λₘᵢₙ such that the minimum reflectivity R₀ is achieved at the wavelength λ_{cot}. The wavelength dependence of the reflectivity in this case is represented by the solid line 49a in FIG. 9.

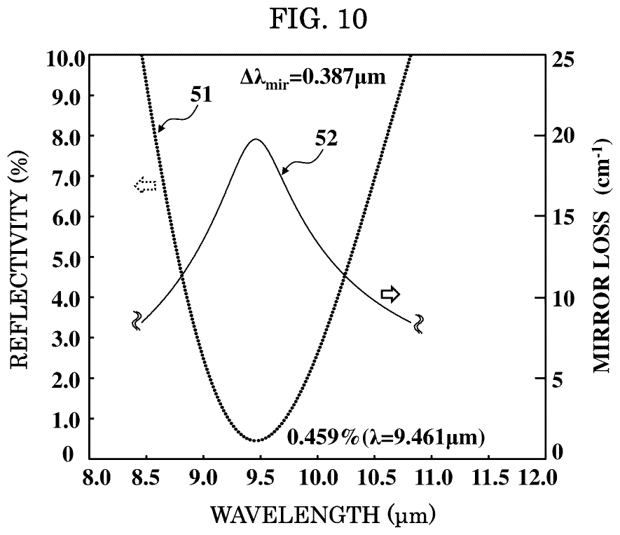

FIG. 10 is a diagram showing the wavelength dependence of the reflectivity and the wavelength dependence of the mirror loss of the coating film shown in FIG. 8 above. In FIG. 10, the dotted line 51 represents the reflectivity R_{f}, which is an enlarged view of the wavelength range and the reflectivity range of the solid line 49 representing the wavelength dependence of the reflectivity shown in the above FIG. 8, and the solid line 52 represents the mirror loss amir. Note that Gold (Au) is coated on the other end surface (rear-end surface) to achieve a reflectivity Rᵣ of approximately 100%. The mirror loss αₘᵢᵣ is calculated using Expression (2) described above.

The mirror loss λₘᵢᵣ has a maximum value of 19.79 cm⁻¹, and the full width of the 10% reduction of the maximum mirror loss (Δλₘᵢᵣ) is 0.387 μm, which is narrower than the full wavelength width Δλ_{qcl} between the two gain values. As described above, if the loss α_{wc}, which is almost independent of wavelength such as waveguide loss and carrier absorption, is 5 cm⁻¹, the maximum value of the total loss αₜ is 24.79 cm⁻¹.

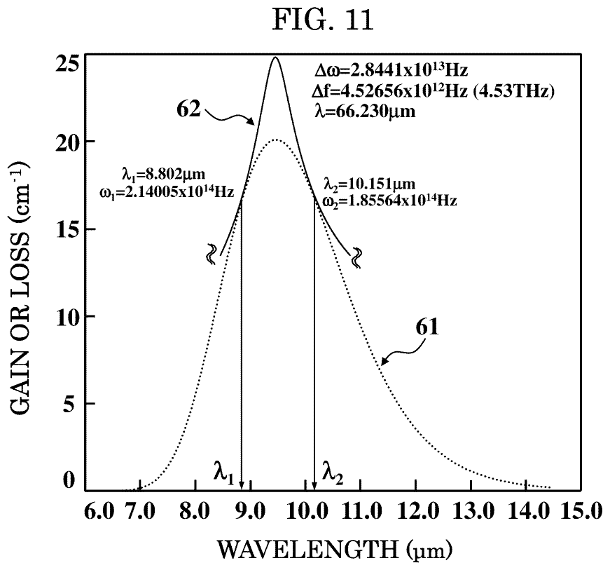

FIG. 11 is a diagram in which the wavelength dependence of the gain and the wavelength dependence of the total loss αₜ are superimposed. In FIG. 11, the dotted line 61 represents the wavelength dependence of the gain and the solid line 62 represents the wavelength dependence of the total loss αₜ. The gain and the total loss αₜ are equal at two points, that are, the wavelength λ₁ and the wavelength λ₂. In general, since a laser oscillates when the gain and the total loss αₜ are equal, the laser oscillates at two wavelengths in one quantum cascade laser device 500. The wavelength λ₁ of the first laser oscillation is 8.802 μm, and the wavelength λ₂ of the second laser oscillation is 10.151 μm. The angular frequencies ω₁ and ω₂ are 2.14005×10¹⁴ Hz and 1.85564×10¹⁴ Hz, respectively.

By the nonlinear optical effect of InP crystal, the difference angular frequencies ω₁−ω₂=2.8441×10¹³ Hz and f₁−f₂=4.52656×10¹² Hz (4.53 THz) can be obtained. The wavelength corresponding to the difference frequencies f₁−f₂ is 66.230 μm.

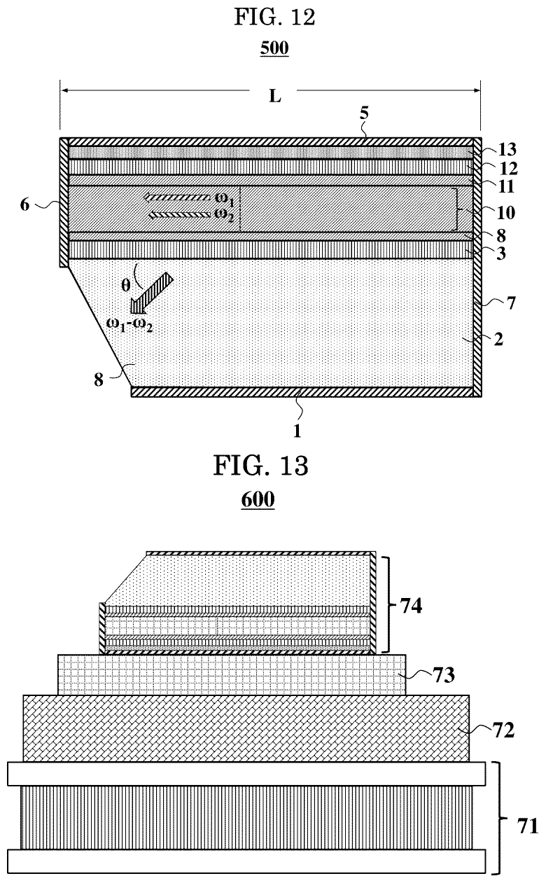

FIG. 12 is a cross-sectional view of the quantum cascade laser device 500 along the xₐ-x_{b} line in FIG. 1 according to Embodiment 1. Terahertz waves (ω₁-ω₂) are emitted in the Cherenkov angle (θ) direction which satisfies the phase matching condition. Normally, the Cherenkov angle θ is about 20°, so that when the laser beam reaches the end surface, the total reflection condition is satisfied and thus cannot be extracted from the quantum cascade laser device 500. Therefore, the end surface thereof is inclined at an angle using polishing or the like, to extract laser light to the outside of the quantum cascade laser device 500. Note that the total number 35 of stages 40 of the quantum cascade laser device 500 is an example, and is not limited thereto, but can be changed according to the required characteristics.

The features of the quantum cascade laser device 500 according to Embodiment 1 are summarized below.

The quantum cascade laser device 500 comprising: the InP substrate 2; the first-conductivity-type (n-type) InP first cladding layer 3 formed above the InP substrate 2; the core region 10 formed above the InP first cladding layer 3 and comprising a plurality of stages 40 each having an active region 38 in which a plurality of barrier layers and a plurality of well layers are formed alternately, and an injector region 39 configured to inject electrons into the active region 38; and the first-conductivity-type, that is, n-type InP second cladding layer 12 formed above the core region 10, wherein the quantum cascade laser device has a cavity length of L and a gain becomes a maximum gain value at a wavelength λ_{qcl} when current is injected, and a low-reflectivity film (the front-end surface coating film 6) is provided on one end surface such that the reflectivity is minimized at a wavelength λ_{cot} configured to be separated from the wavelength λ_{qcl} by a predetermined wavelength where a wavelength width Δλ_{qcl} is defined as a wavelength width between two points in which the gain value decreases by a predetermined ratio of the maximum gain value, and a wavelength width Δλₘᵢᵣ between two points where the mirror loss value is generated by subtracting a predetermined loss value from the maximum mirror loss value calculated from the reflectivity Rᵣ of the other end surface and the cavity length L is set such that the wavelength width Δλₘᵢᵣ is smaller than the wavelength width Δλ_{qcl}.

In Embodiment 1, in consideration of gain asymmetry, the wavelength λ_{cot} (9.461 mm) at which the mirror loss αₘᵢᵣ is maximum is designed to be shifted from the wavelength λ_{qcl} (9.466 μm) at which the gain is maximum. However, when the band of the total loss is wider than the band of the mirror loss mir, and the total loss and the gain are equal at the two wavelengths, the wavelength λ_{cot} may be the same as the wavelength λ_{qcl}.

The low-reflectivity film having the desired minimum reflectivity (R₀) at the desired wavelength (λ_{cot}) provided on the end surface of the quantum cascade laser device utilizes the idea of the method for designing a low-reflectivity film according to Embodiment 1, and it is not necessary for each coating film of the multi-layer coating film to exactly match the value shown in Embodiment 1. That is, if the band of the mirror loss αₘᵢᵣ calculated from the low-reflectivity film is narrower than the gain band of the quantum cascade laser device, the low-reflectivity film functions sufficiently.

### Effects of Embodiment 1

As described above, in the quantum cascade laser device according to Embodiment 1, when the gain achieves a maximum gain value at wavelength λ_{qcl} during current injection, a low-reflectivity film whose reflectivity becomes the minimum at the wavelength λ_{cot}, which is the wavelength separated by a predetermined wavelength from the wavelength width Δλ_{qcl}, where a wavelength width Δλ_{qcl} is defined as a wavelength width between two points in which the gain value decreases by a predetermined ratio of the maximum gain value, is provided on one end surface. Then, a wavelength width Δλₘᵢᵣ between two points where the mirror loss value is generated by subtracting a predetermined loss value from the maximum mirror loss value is set such that the wavelength width Δλₘᵢᵣ is smaller than the wavelength width Δλ_{qcl}. Therefore, a quantum cascade laser device that can easily achieve terahertz oscillation can be obtained.

### Embodiment 2

FIG. 13 is a cross-sectional view of the quantum cascade laser device 600 according to Embodiment 2. The quantum cascade laser device 600 according to Embodiment 2 includes a temperature control device 71. That is, in the quantum cascade laser device 600 according to Embodiment 2, the quantum cascade laser device 74 is mounted on the temperature control device 71 such as a Peltier device. The quantum cascade laser device 74 is the same as the quantum cascade laser device 500 according to Embodiment 1.

As shown in FIG. 13, the quantum cascade laser device 74 according to Embodiment 2 includes: the temperature control device 71; a metal block 72 bonded on the temperature control device 71; a sub-mount 73 bonded on the metal block 72; and the quantum cascade laser device 74 bonded on the sub-mount 73. The quantum cascade laser device 74 is bonded to the sub-mount 73 with the epitaxial crystal growth layer side facing down (epi-side down) to reduce thermal resistance.

The distribution of the total loss αₜ consisting of mirror loss λₘᵢᵣ, waveguide loss, carrier absorption, and the like is almost independent of temperature, while the gain distribution depends on temperature and shifts toward longer wavelengths as the temperature increases.

Injecting current into the quantum cascade laser device 74 to increase the gain, and driving the temperature control device 71 to change the temperature of the quantum cascade laser device 74, even if the gain peak wavelength and the maximum wavelength of the mirror loss αₘᵢᵣ are preliminarily adjusted relatively roughly, it is possible to easily equalize the gain and the total loss αₜ at two wavelengths, thereby enabling simple terahertz oscillation.

Furthermore, even if the gain distribution fluctuates due to time-dependent changes during operation and terahertz oscillation stops due to single-wavelength oscillation, it is possible to easily restore two-wavelength oscillation by adjusting the current injection amount to the quantum cascade laser device 74 and the temperature by the temperature control device 71, thereby enabling easy restoration of terahertz oscillation.

### Effects of Embodiment 2

As described above, in the quantum cascade laser device according to Embodiment 2, the temperature control of the quantum cascade laser device by the temperature control device enables easy restoration of terahertz oscillation in the quantum cascade laser device.

### Embodiment 3

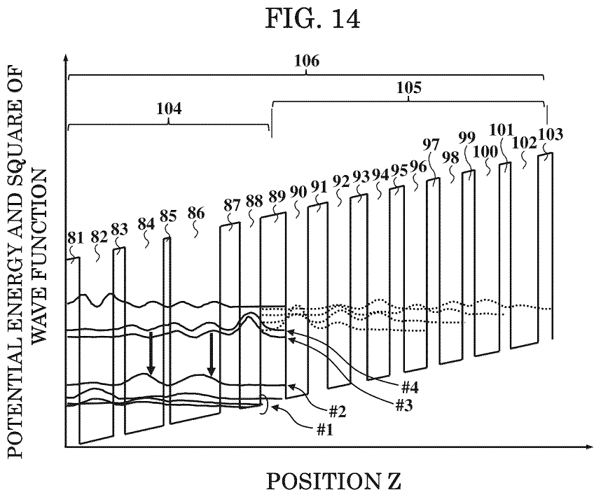

The quantum cascade laser device according to the present disclosure is characterized in that the gain band is wider than the band of the mirror loss αₘᵢᵣ. Accordingly, Embodiment 3 shows an example of expanding the gain band of a quantum cascade laser device. FIG. 14 shows the quantum well structure of one stage 106 and the square of the wave function at each energy level in the quantum cascade laser device according to Embodiment 3, which is the structure described in Non-Patent Document 4.

As shown in FIG. 14, one stage 106 comprises an active region 104 and an injector region 105.

The active region 104 comprises: an undoped AlInAs barrier layer 81 having a thickness of 1.8 nm; an undoped GaInAs well layer 82 having a thickness of 5.2 nm; an undoped AlInAs barrier layer 83 having a thickness of 1.5 nm; an undoped GaInAs well layer 84 having a thickness of 5.8 nm; an undoped AlInAs barrier layer 85 having a thickness of 0.7 nm; an undoped GaInAs well layer 86 having a thickness of 7.5 nm; an undoped AlInAs barrier layer 87 having a thickness of 2.7 nm; an undoped GaInAs well layer 88 having a thickness of 3.1 nm; and a part of an undoped AlInAs barrier layer 89 having a thickness of 3.7 nm.

The injector region 105 comprises: a remaining part of the undoped AlInAs barrier layer 89 having a thickness of 3.7 nm; an undoped GaInAs well layer 90 having a thickness of 3.3 nm; an undoped AlInAs barrier layer 91 having a thickness of 2.8 nm; an undoped GaInAs well layer 92 having a thickness of 3.4 nm; an undoped AlInAs barrier layer 93 having a thickness of 2.3 nm; an undoped GaInAs well layer 94 having a thickness of 3.4 nm; an n-type AlInAs barrier layer 95 having a thickness of 2.0 nm and doped to be n-type; an n-type GaInAs well layer 96 having a thickness of 3.4 nm and doped to be n-type; an n-type AlInAs barrier layer 97 having a thickness of 1.7 nm and doped to be n-type; an n-type GaInAs well layer 98 having a thickness of 3.5 nm and doped to be n-type; an undoped AlInAs barrier layer 99 having a thickness of 1.6 nm; an undoped GaInAs well layer 100 having a thickness of 3.8 nm; an undoped AlInAs barrier layer 101 having a thickness of 1.5 nm; an undoped GaInAs well layer 102 having a thickness of 4.1 nm; and an undoped AlInAs barrier layer 103 having a thickness of 1.8 nm.

There are two upper energy levels, that is, an energy level #3 and an energy level #4, and one lower energy level, that is, an energy level #2, which contribute to light emission. To quickly extract electrons from lower energy levels, there is a ground energy level #1 under the lower energy levels. Such a structure is called dual-upper-state to single-lower-state transition (DAU/SS), and has a wider gain band than a single transition process.

### Effects of Embodiment 3

As described above, in the quantum cascade laser device according to Embodiment 3, the gain band of the quantum cascade laser device is wider than the band of the mirror loss derived from the reflectivity film provided on the end surface thereof, thus providing an effect that terahertz waves can be easily oscillated.

### Embodiment 4

The quantum cascade laser device according to the present disclosure is characterized in that the gain band is wider than the band of the mirror loss αₘᵢᵣ. Accordingly, Embodiment 4 shows an example of expanding the gain band of a quantum cascade laser device.

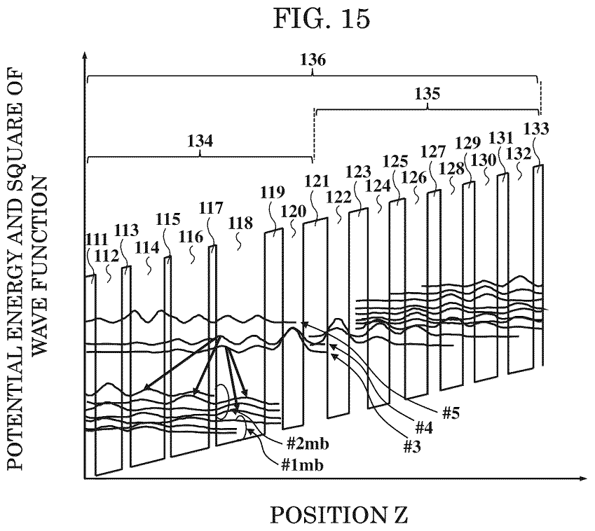

FIG. 15 shows the quantum well structure of one stage 136 and the square of the wave function at each energy level in the quantum cascade laser device according to Embodiment 4, which is the structure described in Non-Patent Document 5.

As shown in FIG. 15, one stage 136 comprises an active region 134 and an injector region 135.

The active region 134 comprises: an undoped AlInAs barrier layer 111 having a thickness of 1.5 nm; an undoped GaInAs well layer 112 having a thickness of 4.1 nm; an undoped AlInAs barrier layer 113 having a thickness of 1.2 nm; an undoped GaInAs well layer 114 having a thickness of 5.2 nm; an undoped AlInAs barrier layer 115 having a thickness of 1.0 nm; an undoped GaInAs well layer 116 having a thickness of 5.8 nm; an undoped AlInAs barrier layer 117 having a thickness of 0.9 nm; an undoped GaInAs well layer 118 having a thickness of 7.5 nm; an undoped AlInAs barrier layer 119 having a thickness of 2.7 nm; an undoped GaInAs well layer 120 having a thickness of 3.1 nm; and a part of an undoped AlInAs barrier layer 121 having a thickness of 3.7 nm.

The injector region 135 comprises: a remaining part of the undoped AlInAs barrier layer 121 having a thickness of 3.7 nm; an undoped GaInAs well layer 122 having a thickness of 3.3 nm; an undoped AlInAs barrier layer 123 having a thickness of 2.8 nm; an undoped GaInAs well layer 124 having a thickness of 3.4 nm; an undoped AlInAs barrier layer 125 having a thickness of 2.3 nm; an undoped GaInAs well layer 126 having a thickness of 3.4 nm; an n-type AlInAs barrier layer 127 having a thickness of 2.0 nm and doped to be n-type; an n-type GaInAs well layer 128 having a thickness of 3.4 nm and doped to be n-type; an n-type AlInAs barrier layer 129 having a thickness of 1.7 nm and doped to be n-type; an n-type GaInAs well layer 130 having a thickness of 3.5 nm and doped to be n-type; an undoped AlInAs barrier layer 131 having a thickness of 1.6 nm; an undoped GaInAs well layer 132 having a thickness of 3.8 nm; and an undoped AlInAs barrier layer 133 having a thickness of 1.5 nm.

The two upper energy levels are an energy level #3 and an energy level #4, and the lower energy level is miniband #2mb consisting of four sub-bands, which contribute to light emission. To quickly extract electrons from lower energy levels, there is a ground energy level #1mb, which comprises three sub-bands, under the lower energy levels. Such a structure is called dual-upper-state to single-lower-state transition (DAU/SS), and has a wider gain band than the DAU/SS of Embodiment 3.

### Effects of Embodiment 4

As described above, in the quantum cascade laser device according to Embodiment 4, the gain band of the quantum cascade laser device is wider than the band of the mirror loss derived from the reflectivity film provided on the end surface thereof, thus providing an effect that terahertz waves can be oscillated more easily.

### Embodiment 5

The quantum cascade laser device according to Embodiment 5 is characterized in that the gain band of a quantum cascade laser device is wider than the band of the mirror loss αₘᵢᵣ. In Embodiments 3 and 4, an example in which the gain band of the quantum cascade laser device is expanded is shown, but in Embodiment 5, an example in which the mirror loss band αₘᵢᵣ is narrowed is shown.

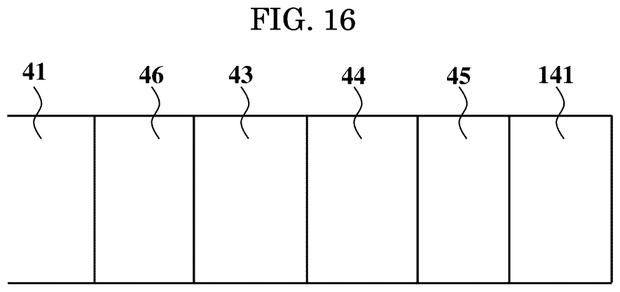

FIG. 16 is a schematic diagram showing a part of the quantum cascade laser device according to Embodiment 5. In FIG. 7 showing Embodiment 1, a coating film 141 is added outside the third coating film 45. In FIG. 16, the coating film 141 has a refractive index n_{b} and a thickness d_{b} of λ_{cot}/(2n_{b}). The characteristic matrix of a five-layer coating film is expressed by the following Expression (13).

$$\begin{matrix}[ Mathematical 11 ] & \\ ( \begin{matrix}{m}_{11} & {m}_{12} \\ {m}_{21} & {m}_{22}\end{matrix} ) = ( \begin{matrix}cos {ϕ}_{a} & \frac{- i}{{n}_{a}} sin {ϕ}_{a} \\ - i {n}_{a} sin {ϕ}_{a} & cos {ϕ}_{a}\end{matrix} ) ( \begin{matrix}cos {ϕ}_{1} & \frac{- i}{{n}_{1}} sin {ϕ}_{1} \\ - i {n}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - i {n}_{2} sin {ϕ}_{2} & cos {ϕ}_{2}\end{matrix} ) ( \begin{matrix}cos {ϕ}_{3} & \frac{- i}{{n}_{1}} sin {ϕ}_{3} \\ - i {n}_{3} sin {ϕ}_{3} & cos {ϕ}_{3}\end{matrix} ) ( \begin{matrix}cos b & \frac{- i}{{n}_{b}} sin {ϕ}_{b} \\ - i {n}_{b} sin {ϕ}_{b} & cos {ϕ}_{b}\end{matrix} ) & ( 13 )\end{matrix}$$

In Expression (13), the phase terms Φₐ, Φ₁, Φ₂, β₃ and Φ_{b} of each coating film are expressed by the following Expression (14), and thicknesses of the inserted coating film 46 and the additional coating film 141 are expressed by the following Expression (15), respectively.

$$\begin{matrix}[ Mathematical 12 ] & \\ {ϕ}_{a} = 2 π {n}_{a} {d}_{a} / {λ}_{c ot} , {ϕ}_{1} = 2 π {n}_{1} {d}_{1} / {λ}_{c ot} , {ϕ}_{2} = 2 π {n}_{2} {d}_{2} / {λ}_{co t} , \\ {ϕ}_{3} = 2 π {n}_{3} {d}_{3} / {λ}_{co t} , {ϕ}_{b} = 2 π {n}_{b} {d}_{b} / {λ}_{co t} & ( 14 )\end{matrix}$$

$${d}_{a} = {λ}_{c ot} / ( 2 {n}_{a} ) , {d}_{b} = {λ}_{co t} / ( 2 {n}_{b} ) \qquad ( 15 )$$

As an example, if the additional coating film 141 is ZnS having the refractive index n_{b} of 2.20, the thickness thereof is d_{b}=λ_{cot}/(2n_{b})=2150.20 nm at the wavelength of λ_{cot}=9.461 μm.

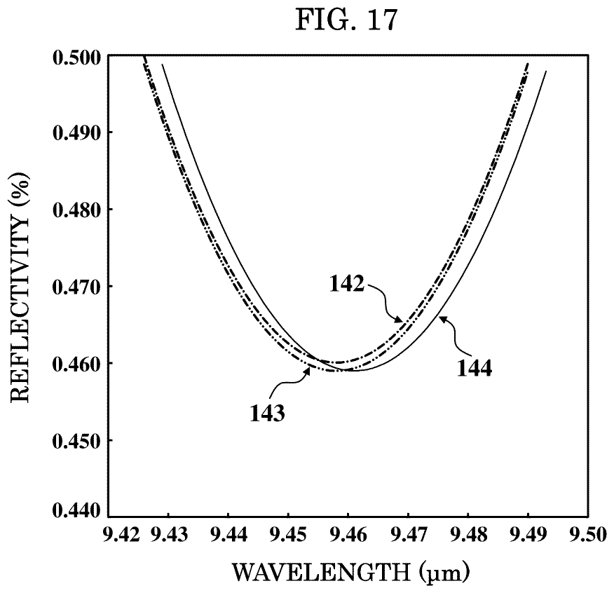

The wavelength dependence of the reflectivity when the coating film 141 is provided on the final layer of the coating films having the above-mentioned thicknesses dₐ=2782.600 nm, d₁=609.328 nm, d₂=183.785 nm, and d₃=697.248 nm (double-dash line 48 in FIG. 8) is shown in the dash-dot line 142 in FIG. 17. At the wavelength of λₘᵢₙ=9.458 μm, the minimum reflectivity value Rₘᵢₙ⁰ of the five-layer coating film is 0.4600%.

While the minimum reflectivity R₀^{a} of the single-layer coating film is 0.460388%, the minimum reflectivity value Rₘᵢₙ⁰ of the five-layer coating film is 0.4600%, which is lower than the minimum reflectivity R₀^{a} of the single-layer coating film, but higher than the desired minimum reflectivity R₀. Accordingly, the setting reflectivity R₁ is set to be 0.459324% in Expression (11) so as to achieve the desired minimum reflectivity R₀ for the minimum refractivity value Rₘᵢₙ of the five-layer coating film, thus the refractive index n_{fl}¹ of the single-layer coating film is calculated to be 1.6714607.

Solving Expression (12), the thickness of each coating film is calculated to be d₁=609.347 nm, d₂=183.756 nm, and d₃=697.284 nm, respectively. When the coating film 46 having the refractive index nₐ of 1.70 and the thickness dₐ of 2782.60 nm is inserted between the end surface of the quantum cascade laser device 41 and the first coating film 43, and the coating film 141 having the refractive index n_{b} of 2.20 and the thickness d_{b} of 2150.20 nm is provided as the final coating film, the wavelength dependence of the reflectivity is shown by the double-dash line 143 in FIG. 17. The minimum reflectivity value Rₘᵢₙ of the five-layer coating film is 0.459% at the wavelength λₘᵢₙ=9.458 μm, and the desired minimum reflectivity of 0.459% can be achieved.

Next, when the thickness of each coating film is multiplied by λ_{cot}/λₘᵢₙ, the thickness of each coating film is calculated to be dₐ=2783.4826 nm, d₁=609.5403 nm, d₂=183.8143 nm, d₃=697.5052 nm, and d_{b}=2150.8820 nm, respectively. The wavelength dependence of the reflectivity in this case is shown by the solid line 144 in FIG. 17. It can be seen that the minimum reflectivity is 0.459% at the wavelength λ₀=9.461 μm.

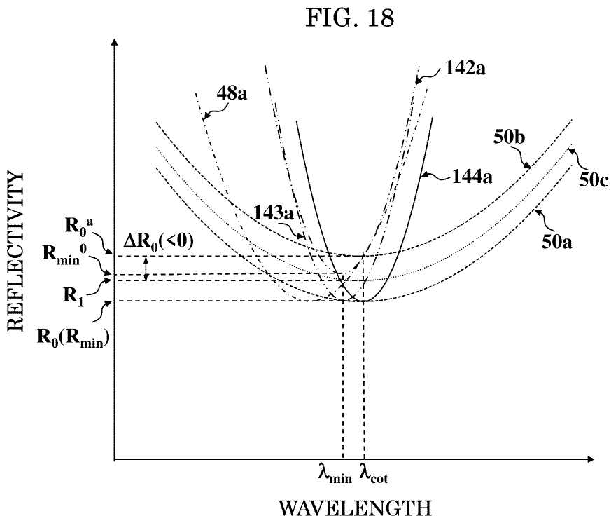

The above method for replacement will be described with reference to FIG. 18.
(1) The dashed line 50a in FIG. 18 represents the wavelength dependence of the reflectivity of the single-layer coating film having the minimum reflectivity R₀ at the desired wavelength λ_{cot}. The dashed line 48a in FIG. 18 represents the wavelength dependence of the reflectivity of the four-layer coating film (each thickness: dₐ=2782.600 nm, d₁=609.328 nm, d₂=183.785 nm, d₃=697.248 nm (double-dash line 48 in FIG. 8)) of Embodiment 1.
(2) The wavelength dependence of the reflectivity of the five-layer coating film in which the coating film 141 is provided on the final layer of the four-layer coating film is represented by the double-dash line 142a in FIG. 18. Since the coating film 141 has the refractive index n_{b} and the thickness of d_{b}=λ_{cot}/(2n_{b}), the reflectivity is not affected at the wavelength λ_{cot}, and the reflectivity of the five-layer coating film at the wavelength λ_{cot} is R₀^{a}=0.460388%, which is the same as the setting reflectivity of the four-layer coating film. The minimum reflectivity Rₘᵢₙ⁰ of the five-layer coating film is 0.4600%. The refractive index n_{fl}¹ of the single-layer coating film having the minimum reflectivity R₀^{a} (=0.460388%) at the wavelength λ_{cot} is 1.67132893 for the four-layer coating film described above, and the wavelength dependence of the reflectivity of the single-layer coating film is represented by the dashed line 50b in FIG. 18. That is, if the single-layer coating film having the minimum reflectivity R₀^{a} at the wavelength λ_{cot} (the wavelength dependence of the reflectivity is represented by the dashed line 50b) is replaced by the five-layer coating film including the first coating film having the refractive index nₐ and the thickness of dₐ=λ_{cot}/(2ₙₐ) in contact with the quantum cascade laser device and the final coating film having the refractive index n_{b} and the thickness of d_{b}=λ_{cot}/(2n_{b}), the wavelength dependence of the reflectivity is represented by the double-dash line 142a in FIG. 18, and the reflectivity of the five-layer coating film becomes a minimum value of Rₘᵢₙ⁰ at the wavelength λₘᵢₙ.
(3) While the minimum reflectivity R₀^{a} of the single-layer coating film is 0.460388%, the minimum reflectivity value Rₘᵢₙ⁰ of the five-layer coating film is 0.4600%, which is lower than the minimum reflectivity R₀^{a} of the single-layer coating film, but higher than the desired minimum reflectivity R₀. Accordingly, the setting reflectivity R₁ is set to be 0.459324% in Expression (11) so as to achieve the desired minimum reflectivity R₀ for the minimum refractivity value Rₘᵢₙ of the five-layer coating film, thus the refractive index n_{fl}¹ of the single-layer coating film is calculated to be 1.6714607. Solving Expression (12), the thickness of each coating film is calculated, and the coating film 46 having the refractive index nₐ and the thickness dₐ is inserted between the end surface of the quantum cascade laser device 41 and the first coating film 43, and the coating film 141 having the refractive index no and the thickness d_{b} is provided as the final coating film, and then the wavelength dependence of the reflectivity is calculated (double-dash line 143a in FIG. 18). The desired minimum reflectivity value R₀ is achieved at the wavelength λₘᵢₙ.
(4) The thickness of each coating film of the five-layer coating film is multiplied by λ_{cot}/λₘᵢₙ such that the minimum reflectivity R₀ is achieved at the wavelength λ_{cot}. The wavelength dependence of the reflectivity in this case is represented by the solid line 144a in FIG. 18.

The low-reflectivity film having the desired minimum reflectivity (R₀) at the desired wavelength (λ_{cot}) provided on the end surface of the quantum cascade laser device utilizes the idea of the method for designing a low-reflectivity film according to Embodiment 5, and it is not necessary for each coating film of the multi-layer coating film to exactly match the value shown in Embodiment 5. That is, if the band of the mirror loss αₘᵢᵣ calculated from the low-reflectivity film is narrower than the gain band of the quantum cascade laser device, the low-reflectivity film functions sufficiently.

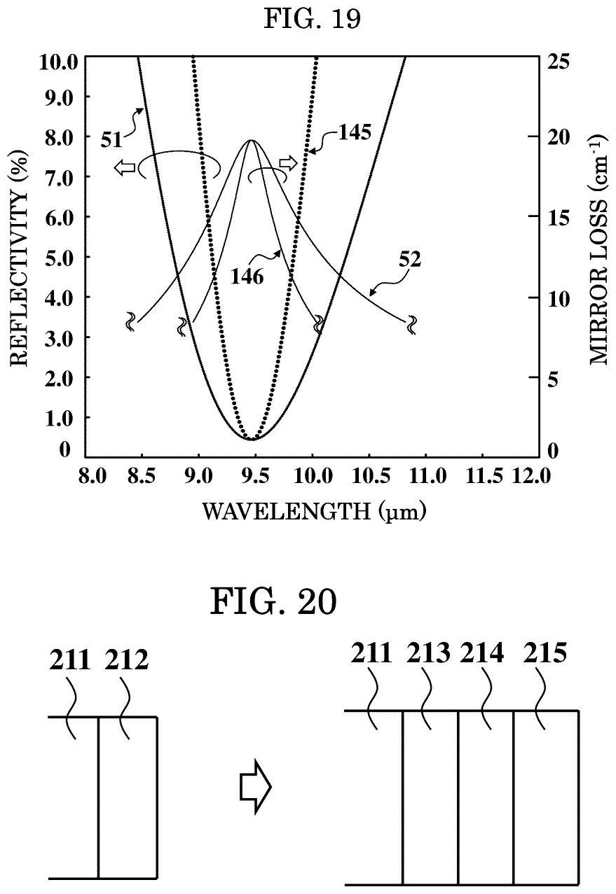

FIG. 19 shows the wavelength dependence of reflectivity and mirror loss αₘᵢᵣ in Embodiment 5 in comparison with Embodiment 1. In FIG. 19, the dotted line 145 represents the wavelength dependence of reflectivity and the solid line 146 represents the wavelength dependence of the mirror loss mir/respectively. From FIG. 19, it can be seen that the minimum reflectivity and the maximum mirror loss do not change, and the reflectivity distribution and the mirror loss distribution become narrower. The full width (Δλₘᵢᵣ) at two points reduced by 10% with respect to the maximum mirror loss is 0.184 μm, which is about half that of Embodiment 1.

### Effects of Embodiment 5

As described above, in the quantum cascade laser device according to Embodiment 5, the state in which the mirror loss αₘᵢᵣ of the quantum cascade laser device is narrower than the gain band can be easily achieved, thus providing an effect that terahertz waves can be oscillated more easily.

One of the components of the present disclosure is to achieve the desired minimum reflectivity (R₀) at the desired wavelength (λ_{cot}) and, consequently, the desired maximum mirror loss at the desired wavelength. Accordingly, a method for achieving the desired minimum reflectivity at the desired wavelength will be described in detail below.

When the quantum cascade laser device 211 having an effective refractive index n_{c} is provided with a coating film composed of a single-layer coating film having a refractive index n_{f} at the wavelength λ_{cot} and a thickness set to λ₀/(4n_{f}), the reflectivity of the single-layer coating film becomes a minimum reflectivity R₀. The minimum reflectivity R₀ is expressed by the above-mentioned Expression (3).

Conversely, from Expression (3), the refractive index n_{f} and the refractive index n_{fh} of the coating film to achieve the desired minimum reflectivity R₀ are calculated using the above Expression (4).

For example, when the effective refractive index n_{c} of the quantum cascade laser device 211 is 3.2 and the minimum reflectivity R₀ is 0.005 (0.5%), the refractive index n_{fl} and the refractive index n_{fh} are calculated to be 1.666535 and 1.920152, respectively. Unfortunately, there is currently no material constituting the coating film that has these refractive index values and is applicable to the optical semiconductor device. Consequently, in the present disclosure, the above-described refractive index values are achieved by substituting with known materials.

First, the case where the refractive index n_{fl}=1.666535 will be described. Consider the replacement of a single-layer coating film with a three-layer coating film formed of two materials in which one material has a refractive index lower than the refractive index n_{fl} and the other material has a refractive index higher than the refractive index n_{fl}.

FIG. 20 is a schematic diagram of the case where a single-layer coating film 212 having the refractive index n_{fl} and a thickness d_{fl} of λ_{cot}/(4n_{fl}) is replaced with a three-layer coating film in which each coating film has a refractive index n₁ and a thickness d₁, a refractive index n₂ and a thickness d₂, and a refractive index n₁ and a thickness d₃, respectively. As shown in FIG. 20, the single-layer coating film 212 having the refractive index n_{fl} (=1.66535) and the thickness d_{fl}=λ_{cot}/(4n_{fl}) formed on the end surface of the quantum cascade laser device 211 emitting light at the wavelength of λ_{cot} and having the effective refractive index n_{c} is replaced with the three-layer coating film composed of a first coating film 213 having the refractive index n₁ and the thickness d₁, a second coating film 214 having the refractive index n₂ and the thickness d₂, and a third coating film 215 having the refractive index n₁ and the thickness d₃. Assuming that the single-layer coating film 212 can be replaced with the three-layer coating film, the characteristic matrices of both coating films are equal, as represented by the following Expression (16).

$$\begin{matrix}[ Mathematical 13 ] & \\ ( \begin{matrix}0 & \frac{- i}{{n}_{fl}} \\ - i {n}_{fl} & 0\end{matrix} ) = ( \begin{matrix}cos {ϕ}_{1} & \frac{- i}{{n}_{1}} sin {ϕ}_{1} \\ - i {n}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - i {n}_{2} sin {ϕ}_{2} & cos {ϕ}_{2}\end{matrix} ) ( \begin{matrix}cos {ϕ}_{3} & \frac{- i}{{n}_{1}} sin {ϕ}_{3} \\ - i {n}_{1} sin {ϕ}_{3} & cos {ϕ}_{3}\end{matrix} ) & ( 16 )\end{matrix}$$

The phase terms Φ₁, Φ₂, and Φ₃ of each coating film in Expression (16) are represented by the following Expression (17).

$$\begin{matrix}[ Mathematical 14 ] & \\ {ϕ}_{1} = 2 π {n}_{1} {d}_{1} / {λ}_{c ot} , {ϕ}_{2} = 2 π {n}_{2} {d}_{2} / {λ}_{c ot} , {ϕ}_{3} = 2 π {n}_{1} {d}_{3} / {λ}_{c ot} & ( 17 )\end{matrix}$$

In Expression (16), since the refractive index n₁ and the refractive index n₂ are known, the unknowns are three thicknesses d₁, d₂, and d₃, and each thickness can be calculated by solving Expression (16).

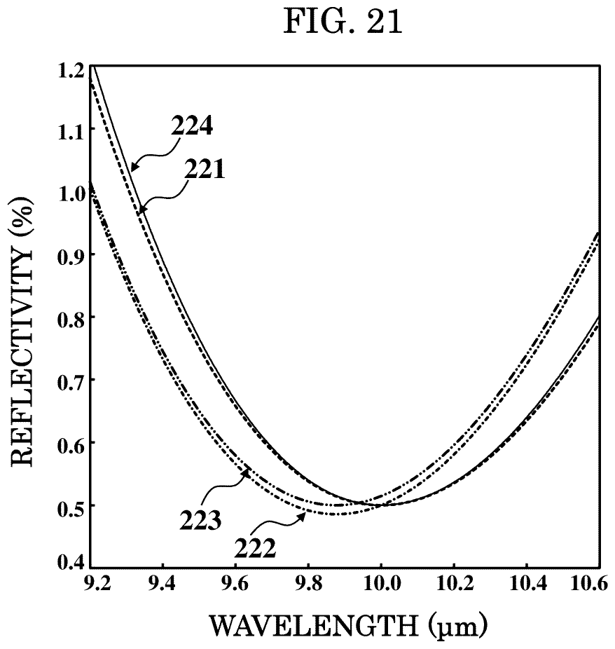

Solving Expression (16), for example, at the wavelength of λ_{cot}=10 μm, YF₃ having a refractive index n₁=1.40 lower than the refractive index n_{fl} for the first coating film 213 and the third coating film 215, and ZnS having a refractive index n₂=2.20 higher than the refractive index n_{fl} for the second coating film 214, the thickness of each coating film is d₁=654.371 nm, d₂=277.806 nm, and d₃=654.371 nm, respectively. The wavelength dependence of the reflectivity in this case is shown by the dash-dot line 222 in FIG. 21. The reflectivity is 0.5% at the wavelength of 10 μm, but this value is not a minimum value, and the minimum reflectivity value Rₘᵢₙ⁰ of the three-layer coating film is 0.4857%.

While the minimum reflectivity R₀ of the single-layer coating film is the 0.5%, minimum reflectivity value Rₘᵢₙ⁰ of the three-layer coating film is 0.4857%, which is lower than the minimum reflectivity R₀ of the single-layer coating film. Thus, the setting reflectivity R₁ is set high so as to achieve the desired minimum reflectivity R₀ for the minimum reflectivity value Rₘᵢₙ of the three-layer coating film. The standard for the reflectivity increment ΔR₀ is R₀−Rₘᵢₙ⁰=0.0143%, and the increment ΔR₀ is adjusted until the setting reflectivity R₁ matches the desired minimum reflectivity R₀. In Embodiment 6, the increment ΔR₀=0.0146%, and the setting reflectivity R₁ is 0.51460%. From the following Expression (18), the refractive index n_{fl}¹ of the single-layer coating film to achieve the setting reflectivity R₁=0.51460% is calculated to be 1.6648189.

$$\begin{matrix}[ Mathematical 15 ] & \\ {n}_{fl}^{1} = {( \frac{1 - \sqrt{{R}_{1}}}{1 + \sqrt{{R}_{1}}} )}^{\frac{1}{2}} \sqrt{{n}_{c}} & ( 18 )\end{matrix}$$

That is, the refractive index n_{fl}¹ of the single-layer coating film to achieve R₁=0.51460% is calculated to be 1.6648189 from Expression (18). Solving the following Expression (19), the thickness of each coating film is calculated to be d₁=655.839 nm, d₂=276.062 nm, and d₃=655.839 nm.

$$\begin{matrix}[ Mathematical 16 ] & \\ ( \begin{matrix}0 & \frac{- i}{{n}_{fl}^{1}} \\ - i {n}_{fl}^{1} & 0\end{matrix} ) = ( \begin{matrix}cos {ϕ}_{1} & \frac{- i}{{n}_{1}} sin {ϕ}_{1} \\ - i {n}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - i {n}_{2} sin {ϕ}_{2} & cos {ϕ}_{2}\end{matrix} ) ( \begin{matrix}cos {ϕ}_{3} & \frac{- i}{{n}_{1}} sin {ϕ}_{3} \\ - i {n}_{1} sin {ϕ}_{3} & cos {ϕ}_{3}\end{matrix} ) & ( 19 )\end{matrix}$$

The wavelength dependence of the reflectivity in this case is shown by the double-dash line 223 in FIG. 21. The minimum reflectivity value Rₘᵢₙ of the three-layer coating film is 0.5% at the wavelength λₘᵢₙ=9.876 μm, and the desired minimum reflectivity of 0.5% can be achieved.

Next, the wavelength λₘᵢₙ of the minimum reflectivity is made to be the desired wavelength λ_{cot}. When the thickness of each coating film is multiplied by λ_{cot}/λₘᵢₙ, the thickness of each coating film is calculated to be d₁=664.074 nm, d₂=279.528 nm, and d₃=664.074 nm, respectively. The wavelength dependence of the reflectivity in this case is shown by the solid line 224 in FIG. 21. It can be seen that the minimum reflectivity is 0.5% at the wavelength λ_{cot}=10 μm.

The dashed line 221 in FIG. 21 shows the wavelength dependence of the reflectivity for the single-layer coating film having the refractive index n_{fl} and a thickness λ_{cot}/(4n_{fl}). The solid line 224 and the dashed line 221 in FIG. 21 do not completely match each other, but show almost the same wavelength dependence of the reflectivity, and the minimum reflectivity and the wavelength at which the minimum reflectivity is achieved are completely identical.

The minimum reflectivity R₀=0.5% and the wavelength λ_{cot}=10 μm are examples and are not limited to these values, which can be set to any desired value. In the above example, YF₃ is used for the first coating film 213 and the third coating film 215, and ZnS is used for the second coating film 214, respectively. However, these are not limited, and it is sufficient to have at least one material whose refractive index is higher than the refractive index n_{fl} and the refractive index n_{fl}¹, and at least one material whose refractive index is lower than the refractive index n_{fl} and the refractive index n_{fl}¹, and the order of each material can be selected arbitrarily.

From the above, it can be understood that the desired minimum reflectivity at the desired wavelength can be achieved using materials with known refractive indices.

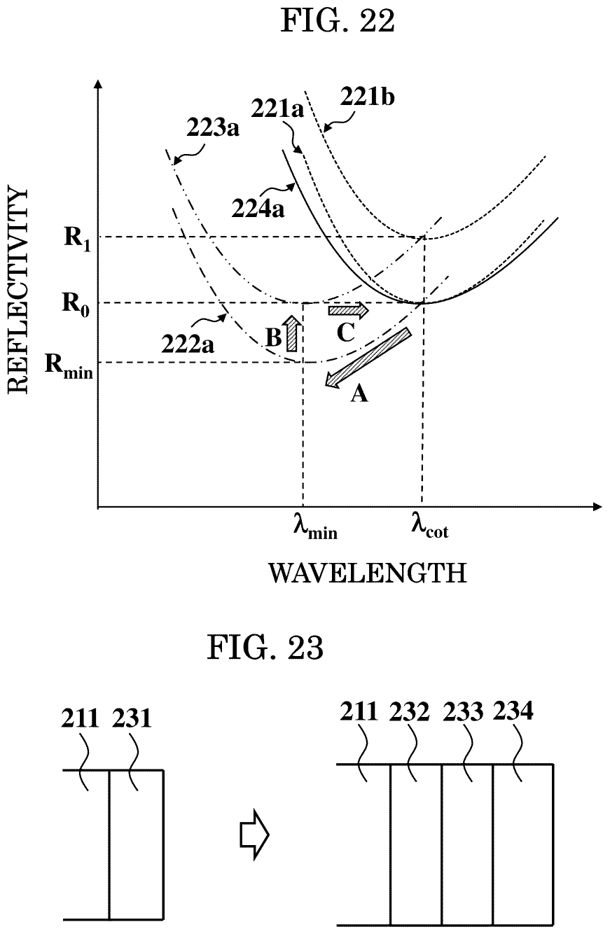

FIG. 22 is a schematic diagram showing a method for replacing the single-layer coating film having the refractive index n_{fl} and the thickness λ_{cot}/(4n_{fl}), and having the minimum reflectivity R₀ at the wavelength λ_{cot}, with the three-layer coating film. In FIG. 22, the dotted line 221a represents the wavelength dependence of the reflectivity of the single-layer coating film having the refractive index n_{fl} and the thickness λ_{cot}/(4n_{fl}), and shows the minimum reflectivity R₀ at the wavelength do.

The above method for replacing will be described below.
(1) In order to replace the single-layer coating film (dashed line 221a) with the three-layer coating film, the thickness of each coating film of the three-layer coating film is determined such that the characteristic matrices of both coating films are equal. In this case, the minimum reflectivity R₀ is achieved at the wavelength λ_{cot}, reflectivity value of the three-layer coating film (the minimum reflectivity value Rₘᵢₙ⁰ of the three-layer coating film) and the wavelength (λₘᵢₙ) at which the minimum reflectivity is achieved are shifted. The wavelength dependence of the reflectivity in this case is represented by the dash-dot line 222a in FIG. 22.
(2) Setting that the setting reflectivity R₁ of the single-layer coating film is R₁=R₀+ΔR₀ (dashed line 221b), calculate the thickness of each layer of the three-layer coating film such that the characteristic matrices are equal, and set the minimum reflectivity at the wavelength λₘᵢₙ such that the minimum reflectivity value Rₘᵢₙ of the three-layer coating film is equal to the desired minimum reflectivity R₀. The wavelength dependence of the reflectivity in this case is represented by the double-dash line 223a in FIG. 22.
(3) The thickness of each coating film of the three-layer coating film is multiplied by λ_{cot}/λₘᵢₙ such that the minimum reflectivity R₀ is achieved at the wavelength λ_{cot}. The wavelength dependence of the reflectivity in this case is represented by the solid line 224a in FIG. 22.

The method for setting the setting reflectivity R₁ will be described in more detail below.

If the minimum reflectivity of the three-layer coating film at the first replacement is Rₘᵢₙ⁰⁽⁰⁾≠R₀, in this case, the difference ΔR₀⁽⁰⁾ from the desired minimum reflectivity R₀ is ΔR₀⁽⁰⁾=R₀−Rₘᵢₙ⁰⁽⁰⁾. Next, the setting reflectivity R₁⁽¹⁾ of the single-layer coating film at the first loop is set to R₁⁽¹⁾=R₀+ΔR₀⁽⁰⁾, and then the minimum reflectivity Rₘᵢₙ⁰⁽¹⁾ is calculated by replacing the single-layer coating film with the three-layer coating film. If the calculated result is Rₘᵢₙ⁰⁽¹⁾=R₀, the calculation ends here. In this case, ΔR₀=ΔR₀⁽⁰⁾ and R₁=R₁⁽¹⁾.

If Rₘᵢₙ⁰⁽¹⁾≠R₀, the loop proceeds to the second loop. In this case, the difference ΔR₀⁽¹⁾ from the desired minimum reflectivity R₀ becomes Δ_{R0}⁽¹⁾=R₀−Rₘᵢₙ⁰⁽¹⁾. The setting reflectivity R₁⁽²⁾ of the single-layer coating film is set to be R₁⁽²⁾=R₀+ΔR₀⁽¹⁾, and then the minimum reflectivity Rₘᵢₙ⁰⁽²⁾ is calculated by replacing the single-layer coating film with the three-layer coating film.

If the calculated result is Rₘᵢₙ⁰⁽²⁾=R₀, the calculation ends here. In this case, ΔR₀=ΔR₀⁽¹⁾ and R₁=R₁⁽²⁾. If Rₘᵢₙ⁰⁽²⁾≠R₀, the loop proceeds to the third loop and the calculation is repeated in the same manner. That is, the setting reflectivity R₁=R₁^{(k)} can be determined by rotating the loop k times until Rₘᵢₙ^{0(k)}=R₀.

The above is how to set the setting reflectivity R₁.

Similarly, the case of the refractive index n_{fh}=1.920152 will be described. Consider the replacement of the single-layer coating film with the three-layer coating film formed of at least two materials in which one material has a refractive index lower than the refractive index n_{fh} and the other material has a refractive index higher than the refractive index n_{fh}.

FIG. 23 is a schematic diagram of the case where the single-layer coating film 231 having the refractive index n_{fh} and a thickness d_{fh} of λ_{cot}/(4n_{fh}) is replaced with the three-layer coating film in which each coating film has the refractive index n₁ and the thickness d₁, the refractive index n₂ and the thickness d₂, and the refractive index n₁ and the thickness d₃, respectively. As shown in FIG. 23, the single-layer coating film 231 having the refractive index n_{fh} (=1.920152) and the thickness d_{fh}=λ_{cot}/(4n_{fh}) formed on the end surface of the quantum cascade laser device 211 emitting light at the wavelength of λ_{cot0} and having the effective refractive index n_{c} is replaced with the three-layer coating film composed of a first coating film 2 having the refractive index n₁ and the thickness d₁, a second coating film 233 having the refractive index n₂ and the thickness de, and a third coating film 234 having the refractive index n₁ and the thickness d₃. The method for replacing the single-layer coating film with the three-layer coating film is the same as in the case of the low refractive index n_{fl} described above, and is performed by solving the following Expression (20).

$$\begin{matrix}[ Mathematical 17 ] & \\ ( \begin{matrix}0 & \frac{- i}{{n}_{fh}} \\ - i {n}_{fh} & 0\end{matrix} ) = ( \begin{matrix}cos {ϕ}_{1} & \frac{- i}{{n}_{1}} sin {ϕ}_{1} \\ - i {n}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - i {n}_{2} sin {ϕ}_{2} & cos {ϕ}_{2}\end{matrix} ) ( \begin{matrix}cos {ϕ}_{3} & \frac{- i}{{n}_{1}} sin {ϕ}_{3} \\ - i {n}_{1} sin {ϕ}_{3} & cos {ϕ}_{3}\end{matrix} ) & ( 20 )\end{matrix}$$

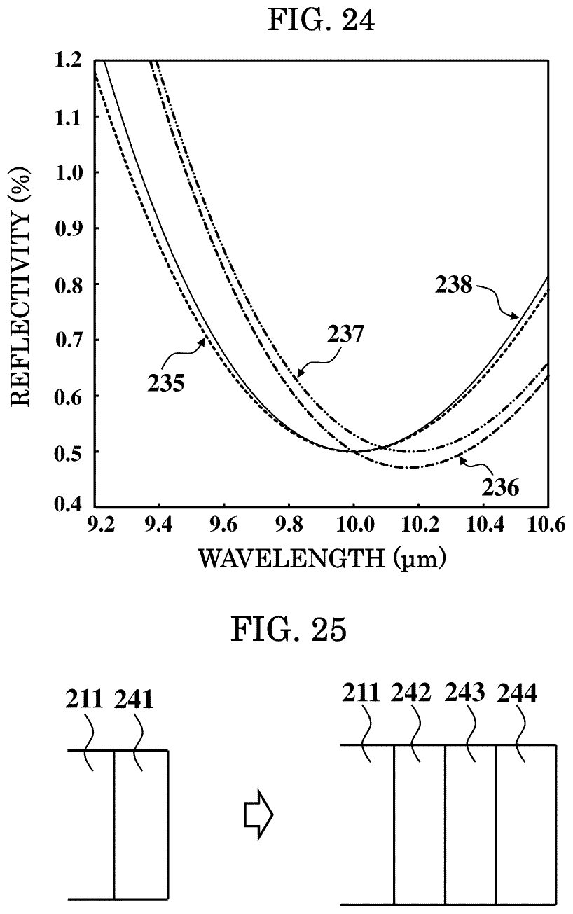

Solving Expression (20), for example, at the wavelength of λ_{cot}=10 μm, using YF₃ having the refractive index n₁=1.40 lower than the refractive index n_{fh} for the first coating film 232 and the third coating film 234, and ZnS having the refractive index n₂=2.20 higher than the refractive index n_{fh} for the second coating film 233, the thickness of each coating film is d₁=434.257 nm, d₂=547.934 nm, and d₃=434.257 nm, respectively. The wavelength dependence of the reflectivity in this case is shown by the dash-dot line 236 in FIG. 24. The reflectivity is 0.5% at the wavelength of 10 μm, but this value is not a minimum value, and the minimum reflectivity value Rₘᵢₙ⁰ of the three-layer coating film is 0.4715%.

While the minimum reflectivity R₀ of the single-layer coating film is 0.5%, the minimum reflectivity value Rₘᵢₙ⁰ of the three-layer coating film is 0.4715%, which is lower than the minimum reflectivity R₀ of the single-layer coating film. Thus, the setting reflectivity R₁ is set as high as 0.53032% so as to achieve the desired minimum reflectivity R₀ for the minimum reflectivity value Rₘᵢₙ of the three-layer coating film as in the case of the low refractive index n_{fl} described above. From the following Expression (21), the refractive index n_{fh}¹ of the single-layer coating film for achieving the setting reflectivity R₁=0.53032% is calculated to be 1.9243333.

$$\begin{matrix}[ Mathematical 18 ] & \\ {n}_{fh}^{1} = {( \frac{1 + \sqrt{{R}_{1}}}{1 - \sqrt{{R}_{1}}} )}^{\frac{1}{2}} \sqrt{{n}_{c}} & ( 21 )\end{matrix}$$

Solving the following Expression (22), the thickness of each coating film is calculated to be d₁=430.513 nm, d₂=552.699 nm, and d₃=430.513 nm, respectively.

$$\begin{matrix}[ Mathematical 19 ] & \\ ( \begin{matrix}0 & \frac{- i}{{n}_{fh}^{1}} \\ - i {n}_{fh}^{1} & 0\end{matrix} ) = ( \begin{matrix}cos {ϕ}_{1} & \frac{- i}{{n}_{1}} sin {ϕ}_{1} \\ - i {n}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - i {n}_{2} sin {ϕ}_{2} & cos {ϕ}_{2}\end{matrix} ) ( \begin{matrix}cos {ϕ}_{3} & \frac{- i}{{n}_{1}} sin {ϕ}_{3} \\ - i {n}_{1} sin {ϕ}_{3} & cos {ϕ}_{3}\end{matrix} ) & ( 22 )\end{matrix}$$

The wavelength dependence of the reflectivity in this case is shown in double-dash line 237 in FIG. 24. The minimum reflectivity value Rₘᵢₙ Of the three-layer coating film is 0.5% at the wavelength λₘᵢₙ=10.174 μm, and the desired minimum reflectivity of 0.5% can be achieved.

Next, the wavelength λₘᵢₙ of the minimum reflectivity is made to be the desired wavelength λ_{cot}. When the thickness of each layer of the three-layer coating film is multiplied by λ_{cot}/λₘᵢₙ, the thickness of each coating film is calculated to be d₁=423.150 nm, d₂=543.247 nm, and d₃=423.150 nm, respectively. The wavelength dependence of the reflectivity in this case is shown in the solid line 238 in FIG. 24. It can be seen that the minimum reflectivity is 0.5% at the wavelength λ_{cot}=10 μm.

The dashed line 235 in FIG. 24 shows the wavelength dependence of the reflectivity for the single-layer coating film having the refractive index n_{fh} and a thickness λ_{cot}/(4n_{fh}). The solid line 238 and the dashed line 235 in FIG. 24 do not completely match each other, but show almost the same wavelength dependence of the reflectivity, and the minimum reflectivity and the wavelength at which the minimum reflectivity is achieved are completely identical.

The minimum reflectivity R₀=0.5% and the wavelength λ_{cot}=10 μm are examples and are not limited to these values, which can be set to any desired value. In the above example, YF₃ is used for the first coating film 232 and the third coating film 234, and ZnS is used for the second coating film 233, respectively. However, these are not limited, and it is sufficient to have at least one material whose refractive index is higher than the refractive index n_{fh} and the refractive index n_{fh}¹, and at least one material whose refractive index is lower than the refractive index n_{fh} and the refractive index n_{fh}¹, and the order of each material can be selected arbitrarily.

From the above, it can be understood that the desired minimum reflectivity at the desired wavelength can be achieved using materials with known refractive indices.

According to the method for manufacturing an optical semiconductor device and the method for designing a low-reflectivity film of Embodiment 1, it is possible to manufacture an optical semiconductor device having a low-reflectivity film controlled to a desired minimum reflectivity at a desired wavelength by replacing the single-layer coating film with the three-layer coating film using the characteristic matrix, and it is also possible to obtain the method for designing a low-reflectivity film.

Next, a case where all three layers of the multi-layer coating are composed of different materials is shown. As a method for designing a low-reflectivity film in this case, an example of the minimum reflectivity R₀=0.01 (1%) is shown. When the effective refractive index n_{c} of the quantum cascade laser device is 3.2, the refractive index n_{f1} and the refractive index n_{fh} are calculated to be 1.618080 and 1.977653, respectively, from the above Expression (4).

First, the case where the refractive index n_{fl}=1.618080 will be described. Consider the replacement of the single-layer coating film with the three-layer coating film formed of three materials in which at least one material has a refractive index lower than the refractive index n_{fl} and at least one material has a refractive index higher than the refractive index n_{fl}.

FIG. 25 is a schematic diagram of the case where a single-layer coating film 241 having the refractive index n_{fl} and the thickness d_{fl} of λ_{cot}/(4n_{fl}) is replaced with the three-layer coating film in which each coating film has the refractive index n₁ and the thickness d₁, the refractive index n₂ and the thickness d₂, and the refractive index n₃ and the thickness d₃. As shown in FIG. 25, the single-layer coating film 241 having the refractive index n_{fl} (=1.618080) and the thickness d_{fl}=λ_{cot}/(4n_{fl}) formed on the end surface of the quantum cascade laser device 211 emitting light at the wavelength of λ_{cot} and having the effective refractive index n_{c} is replaced with the three-layer coating film composed of a first coating film 242 having the refractive index n₁ and the thickness d₁, a second coating film 243 having the refractive index n₂ and the thickness d₂, and a third coating film 244 having the refractive index n₃ and the thickness d₃. Assuming that the single-layer coating film 241 can be replaced with the three-layer coating film, the characteristic matrices of both coating films are equal, as represented by the following Expression (23).

$$\begin{matrix}[ Mathematical 20 ] & \\ ( \begin{matrix}0 & \frac{- i}{{n}_{fl}} \\ - i {n}_{fl} & 0\end{matrix} ) = ( \begin{matrix}cos {ϕ}_{1} & \frac{- i}{{n}_{1}} sin {ϕ}_{1} \\ - i {n}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - i {n}_{2} sin {ϕ}_{2} & cos {ϕ}_{2}\end{matrix} ) ( \begin{matrix}cos {ϕ}_{3} & \frac{- i}{{n}_{1}} sin {ϕ}_{3} \\ - i {n}_{3} sin {ϕ}_{3} & cos {ϕ}_{3}\end{matrix} ) & ( 23 )\end{matrix}$$

In the Expression (23), the phase terms Φ₁, Φ₂, and Φ₃ of each coating film are represented by the following Expression (24).

$$\begin{matrix}[ Mathematical 21 ] & \\ {ϕ}_{1} = 2 π {n}_{1} {d}_{1} / {λ}_{c ot} , {ϕ}_{2} = 2 π {n}_{2} {d}_{2} / {λ}_{co t} , {ϕ}_{3} = 2 π {n}_{3} {d}_{3} / {λ}_{c ot} & ( 24 )\end{matrix}$$

In Expression (23), since the refractive index n₁, the refractive index n₂, and the refractive index n₃ are known, the unknowns are the three thicknesses d₁, d₂, and d₃, and the thickness of each coating film can be calculated by solving Expression (23).

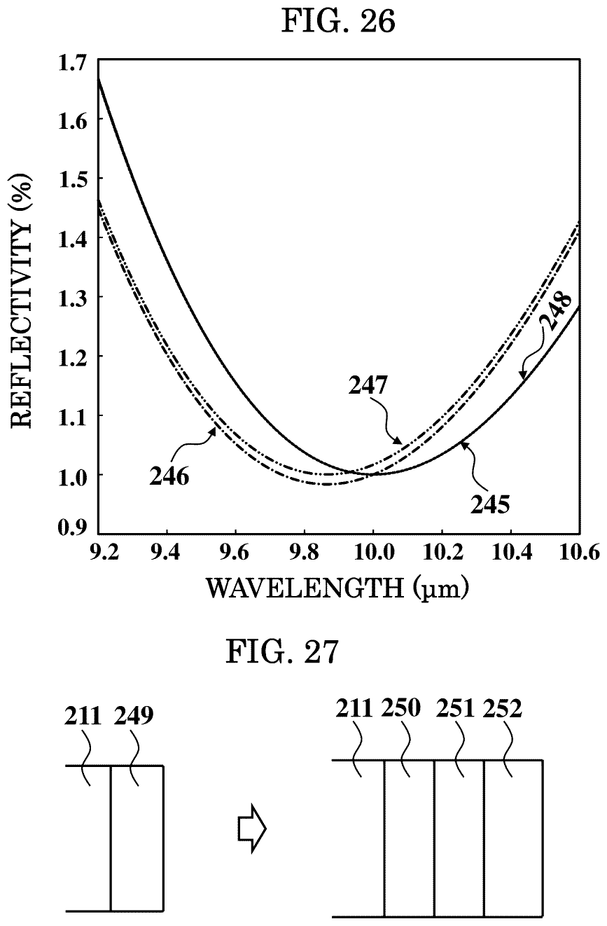

Solving Expression (23), for example, at the wavelength of λ_{cot}=10 μm, YF₃ having the refractive index n₁=1.40 lower than the refractive index n_{fl} for the first coating film 242, ZnS having the refractive index n₂=2.20 higher than the refractive index n_{fl} for the second coating film 243, and CeF₃ having the refractive index n₃=1.45 lower than the refractive index n_{fl} for the third coating film 244, the thickness of each coating film is d₁=640.642 nm, d₂=206.894 nm, and d₃=763.646 nm, respectively. The wavelength dependence of the reflectivity in this case is shown by the dash-dot line 246 in FIG. 26. The reflectivity is 1.0% at the wavelength of 10 μm, but this value is not a minimum value, and the minimum reflectivity value Rₘᵢₙ⁰ of the three-layer coating film is 0.9836%.

While the minimum reflectivity R₀ of the single-layer coating film is 1.0%, the minimum reflectivity value Rₘᵢₙ⁰ of the three-layer coating film is 0.9836%, which is lower than the minimum reflectivity R₀ of the single-layer coating film. Thus, the setting reflectivity R₁ is set as high as 1.01648% so as to achieve the desired minimum reflectivity R₀ for the minimum reflectivity value Rₘᵢₙ of the three-layer coating film. In this case, n_{fl}¹=1.616739 is calculated from Expression (18). Solving the following Expression (25), the thickness of each coating film is calculated to be d₁=641.123 nm, d₂=205.474 nm, and d₃=765.332 nm, respectively.

$$\begin{matrix}[ Mathematical 22 ] & \\ ( \begin{matrix}0 & \frac{- i}{{n}_{fl}^{1}} \\ - i {n}_{fl}^{1} & 0\end{matrix} ) = ( \begin{matrix}cos {ϕ}_{1} & \frac{- i}{{n}_{1}} sin {ϕ}_{1} \\ - i {n}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - i {n}_{2} sin {ϕ}_{2} & cos {ϕ}_{2}\end{matrix} ) ( \begin{matrix}cos {ϕ}_{3} & \frac{- i}{{n}_{1}} sin {ϕ}_{3} \\ - i {n}_{3} sin {ϕ}_{3} & cos {ϕ}_{3}\end{matrix} ) & ( 25 )\end{matrix}$$

The wavelength dependence of the reflectivity in this case is shown by the double-dash line 247 in FIG. 26. The minimum reflectivity value Rₘᵢₙ of the three-layer coating film is 1.0% at the wavelength λₘᵢₙ=9.864 μm, and the desired minimum reflectivity of 1.0% can be achieved.

Next, the wavelength λₘᵢₙ of the minimum reflectivity is made to be the desired wavelength λ_{cot}. When the thickness of each coating film is multiplied by λ_{cot}/λₘᵢₙ, the thickness of each coating film is calculated to be d₁=649.962 nm, d₂=208.307 nm, and d₃=775.884 nm, respectively. The wavelength dependence of the reflectivity in this case is shown by the solid line 248 in FIG. 26. It can be seen that the minimum reflectivity is 1.0% at the wavelength λ_{cot}. The dashed line 245 in FIG. 26 shows the wavelength dependence of the reflectivity for the single-layer coating film having the refractive index n_{fl} and the thickness of λ_{cot}/(4n_{fl}). The solid line 248 and the dashed line 245 in FIG. 26 show almost the same wavelength dependence of the reflectivity, and the minimum reflectivity and the wavelength at which the minimum reflectivity is achieved are completely identical.

The minimum reflectivity R₀=1.0% and the wavelength λ_{cot}=10 μm are examples and are not limited to these values, which can be set to any desired value. In the above example, YF₃ is used for the first coating film 242, ZnS is used for the second coating film 243, and CeF₃ is used for the third coating film 244, respectively. However, these are not limited, and it is sufficient to have at least one material whose refractive index is higher than the refractive index n_{fl} and the refractive index n_{fl}¹, and at least one material whose refractive index is lower than the refractive index n_{fl} and the refractive index n_{fl}¹, and the order of each material can be selected arbitrarily.

From the above, it can be understood that the desired minimum reflectivity at the desired wavelength can be achieved using materials with known refractive indices.

Similarly, the case of the refractive index n_{fh}=1.977653 will be described. Consider the replacement of the single-layer coating film with the three-layer coating film formed of three materials in which at least one material has a refractive index lower than the refractive index n_{fh} and at least one material has a refractive index higher than the refractive index n_{fh}.

FIG. 27 is a schematic diagram of the case where the single-layer coating film 249 having the refractive index n_{fh} and a thickness din of λ_{cot}/(4n_{fh}) is replaced with the three-layer coating film in which each coating film has the refractive index n₁ and the thickness d₁, the refractive index n₂ and the thickness d₂, and the refractive index n₃ and the thickness d₃, respectively. As shown in FIG. 27, the single-layer coating film 249 having the refractive index n_{fh} (=1.977653) and the thickness d_{fh}=λ_{cot}/(4n_{fh}) formed on the end surface of the quantum cascade laser device 211 emitting light at the wavelength of λ_{cot} and having the effective refractive index n_{c} is replaced with the three-layer coating film composed of a first coating film having the refractive index n₁ and the thickness d₁, a second coating film 251 having the refractive index n₂ and the thickness d₂, and a third coating film 252 having the refractive index n₃ and the thickness d₃. The method for replacing the single-layer coating film with the three-layer coating film is the same as the case of the low refractive index described above, and is performed by solving the following Expression (26).

$$\begin{matrix}[ Mathematical 23 ] & \\ ( \begin{matrix}0 & \frac{- i}{{n}_{fh}} \\ - i {n}_{fh} & 0\end{matrix} ) = ( \begin{matrix}cos {ϕ}_{1} & \frac{- i}{{n}_{1}} sin {ϕ}_{1} \\ - i {n}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - i {n}_{2} sin {ϕ}_{2} & cos {ϕ}_{2}\end{matrix} ) ( \begin{matrix}cos {ϕ}_{3} & \frac{- i}{{n}_{1}} sin {ϕ}_{3} \\ - i {n}_{3} sin {ϕ}_{3} & cos {ϕ}_{3}\end{matrix} ) & ( 26 )\end{matrix}$$

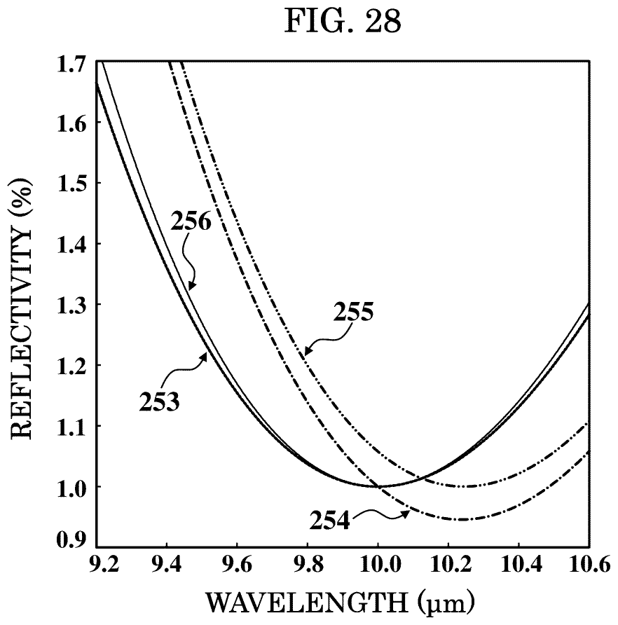

Solving Expression (26), for example, at the wavelength of λ_{cot}=10 μm, using YF₃ having the refractive index n₁=1.40 lower than the refractive index n_{fl} for the first coating film 250, ZnS having the refractive index n₂=2.20 higher than the refractive index n_{fl} for the second coating film 251, and CeF₃ having the refractive index n₃=1.45 lower than the refractive index n_{fl} for the third coating film 252, the thickness of each coating film is d₁=370.115 nm, d₂=607.246 nm, and d₃=395.897 nm, respectively. The wavelength dependence of the reflectivity in this case is shown by the dash-dot line 254 in FIG. 28. The reflectivity is 1.0% at the wavelength of 10 μm, but this value is not a minimum value, and the minimum reflectivity value Rₘᵢₙ⁰ of the three-layer coating film is 0.94561%.

While the minimum reflectivity R₀ of the single-layer coating film is 1.0%, the minimum reflectivity value Rₘᵢₙ⁰ of the three-layer coating film is 0.94561%, which is lower than the minimum reflectivity R₀ of the single-layer coating film. Thus, the setting reflectivity R₁ is set as high as 1.057485% so as to achieve the desired minimum reflectivity R₀ for the minimum reflectivity value Rₘᵢₙ of the three-layer coating film. The refractive index n_{fh}¹ of the single-layer coating film to achieve the setting reflectivity R₁=1.057485% is calculated to be n_{fh}¹=1.9833241 from Expression (21). Solving the following Expression (27), the thickness of each coating film is calculated to be d₁=364.825 nm, d₂=614.601 nm, and d₃=390.009 nm, respectively.

$$\begin{matrix}[ Mathematical 24 ] & \\ ( \begin{matrix}0 & \frac{- i}{{n}_{fh}^{1}} \\ - i {n}_{fh}^{1} & 0\end{matrix} ) = ( \begin{matrix}cos {ϕ}_{1} & \frac{- i}{{n}_{1}} sin {ϕ}_{1} \\ - i {n}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - i {n}_{2} sin {ϕ}_{2} & cos {ϕ}_{2}\end{matrix} ) ( \begin{matrix}cos {ϕ}_{3} & \frac{- i}{{n}_{1}} sin {ϕ}_{3} \\ - i {n}_{3} sin {ϕ}_{3} & cos {ϕ}_{3}\end{matrix} ) & ( 27 )\end{matrix}$$

The wavelength dependence of the reflectivity in this case is shown in double-dash line 255 in FIG. 28. The minimum reflectivity value Rₘᵢₙ Of the three-layer coating film is 1.0% at the wavelength λₘᵢₙ=10.243 μm, and the desired minimum reflectivity of 1.0% can be achieved.

Next, the wavelength λₘᵢₙ of the minimum reflectivity is made to be the desired wavelength λ_{cot}. When the thickness of each coating film is multiplied by λ_{cot}/λₘᵢₙ, the thickness of each coating film is calculated to be d₁=356.170 nm, d₂=600.021 nm, and d₃=380.757 nm, respectively. The wavelength dependence of the reflectivity in this case is shown by the solid line 256 in FIG. 28. It can be seen that the minimum reflectivity is 1.0% at the wavelength λ_{cot}.

The dashed line 253 in FIG. 28 shows the wavelength dependence of the reflectivity for the single-layer coating film having the refractive index n_{fh} and a thickness λ_{cot}/(4n_{fh}). The solid line 256 and the dashed line 253 in FIG. 28 do not completely match each other, but show almost the same wavelength dependence of the reflectivity, and the minimum reflectivity and the wavelength at which the minimum reflectivity is achieved are completely identical.

The minimum reflectivity R₀=1.0% and the wavelength λ_{cot}=10 μm are examples and are not limited to these values, which can be set to any desired value. In the above example, YF₃ is used for the first coating film 250, ZnS is used for the second coating film 251, and CeF₃ is used for the third coating film 252, respectively. However, these are not limited, and it is sufficient to have at least one material whose refractive index is higher than the refractive index n_{fh} and the refractive index n_{fh}¹, and at least one material whose refractive index is lower than the refractive index n_{fh} and the refractive index n_{fh}¹, and the order of each material can be selected arbitrarily.

From the above, it can be understood that the desired minimum reflectivity at the desired wavelength can be achieved using materials with known refractive indices.

### Effects of Embodiment 5

According to the method for designing a low-reflectivity film of Embodiment 5, it is possible to design a low-reflectivity film controlled to a desired minimum reflectivity at a desired wavelength by replacing the single-layer coating film with the three-layer coating film using the characteristic matrix.

It should be noted that a multi-layer coating film having four or more layers made of four or more materials can be designed in the same manner as described in Embodiments 1 and 2 if the thickness of the coating film exceeding three layers is set in advance.

### Embodiment 6

FIG. 29 is an overview of a quantum cascade laser device 700 according to Embodiments 6. The cavity length of the quantum cascade laser device 700 is L and the ridge width thereof is W. The quantum cascade laser device 700 has a buried ridge-type waveguide structure.

As shown in FIG. 29, the quantum cascade laser device 700 includes: an n-type first electrode 153; a semi-insulating InP substrate 151; an n-type InP first cladding layer 3; an Fe-doped InP current blocking layer 4; an n-type GaInAs current injection layer 152; an n-type second electrode 5; a front-end coating film 6; a rear-end coating film 7; and a terahertz light extraction surface 8. FIG. 30 is a cross-sectional view of the quantum cascade laser device 700 along the yₐ-y_{b} line in FIG. 29.

The differences between the quantum cascade laser device 700 according to Embodiment 6 and the quantum cascade laser device 500 according to Embodiment 1 are that the semi-insulating InP substrate 151 is used instead of the n-type InP substrate 2 constituting the quantum cascade laser device 500 according to Embodiment 1, the n-type GaInAs current injection layer 152 is provided on the semi-insulating InP substrate 151 for current injection, and the n-type first electrode 153 is provided on the n-type GaInAs current injection layer 152.

The semi-insulating InP substrate 151 has lower absorption of terahertz waves than the n-type InP substrate 2. Therefore, the quantum cascade laser device 700 can achieve higher output terahertz waves.

### Effects of Embodiment 6

As described above, in the quantum cascade laser device according to Embodiment 6, the semi-insulating InP substrate is used as a semiconductor substrate, thus providing an effect of obtaining a quantum cascade laser device that can achieve terahertz waves with higher output.

### Embodiment 7

FIG. 31 is an overview of a quantum cascade laser device 800 according to Embodiment 7. The cavity length of the quantum cascade laser device 800 is L and the ridge width thereof is W. The quantum cascade laser device 800 has a buried ridge-type waveguide structure. FIG. 32 is a cross-sectional view of the quantum cascade laser device 800 along the yₐ-y_{b} line in FIG. 31.

The difference between the quantum cascade laser device 800 according to Embodiment 7 and the quantum cascade laser device 700 according to Embodiment 6 is that a Si substrate 154 is used instead of the semi-insulating InP substrate 151. The Si substrate 154 has lower absorption of terahertz waves than the n-type InP substrate. Therefore, the quantum cascade laser device 800 can achieve high output terahertz waves. Note that the Si substrate 154 and the n-type GaInAs current injection layer 152 are bonded by bonding technology.

### Effects of Embodiment 7

As described above, in the quantum cascade laser device according to Embodiment 7, the Si substrate is used as a semiconductor substrate, thus providing an effect of obtaining a quantum cascade laser device that can achieve terahertz waves with even higher output.

### Embodiment 8

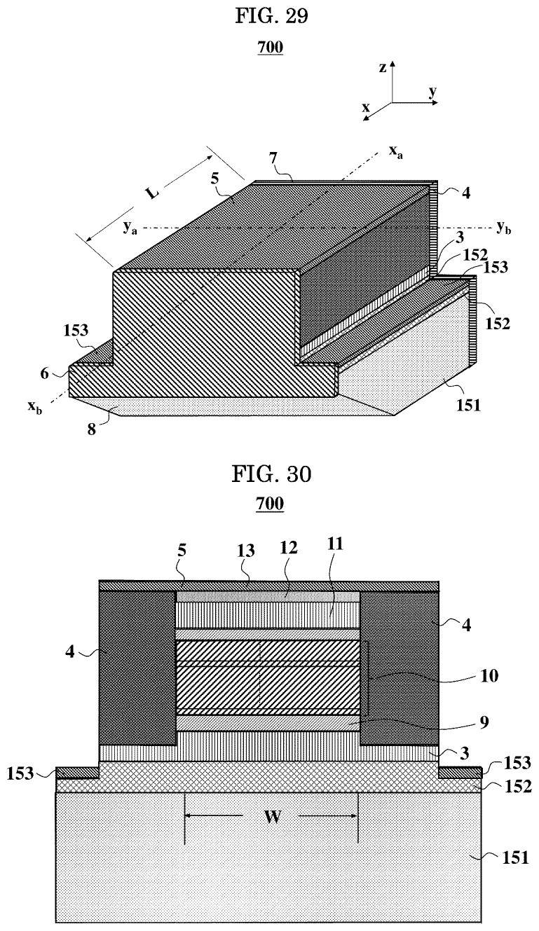

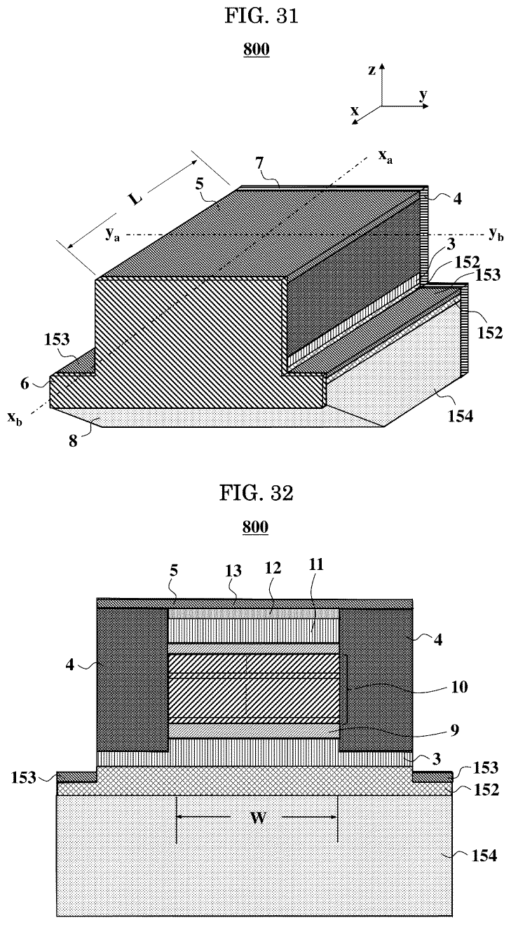

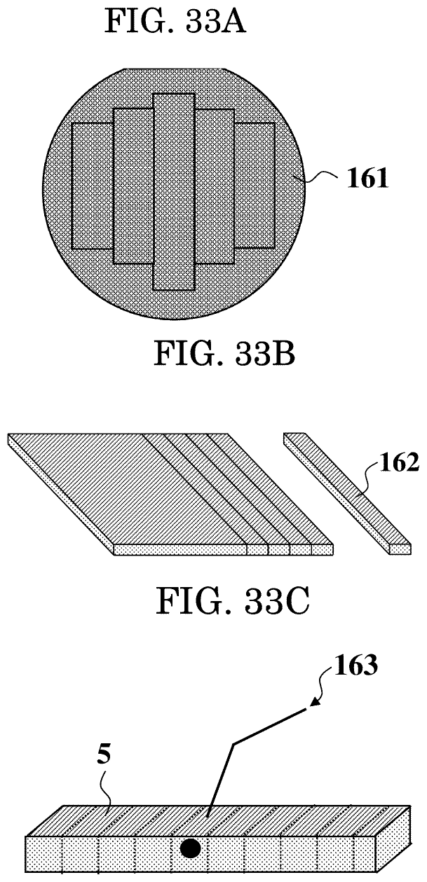

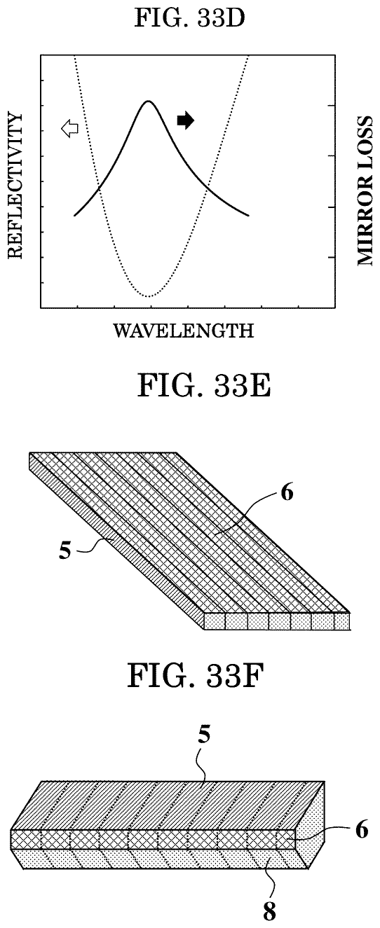

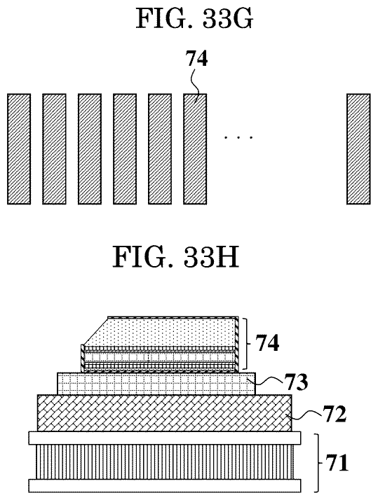

FIGS. 33A to 33H show each step of a method for manufacturing the quantum cascade laser device according to Embodiments 1 to 7. The method for manufacturing the quantum cascade laser device will be described with reference to each figure.
(1) Prepare a wafer 161 after the wafer process is complete (FIG. 33A).
(2) After the wafer 161 is divided into a rectangular block, cleavage bars 162 are fabricated by cleavage (FIG. 33B).
(3) Power is supplied to each quantum cascade laser device using a probe 163 or the like, and then the gain distribution (the wavelength dependence of the gain) is measured (FIG. 33C).
(4) A front-end coating film 6 having a predetermined minimum reflectivity at a desired wavelength is designed on a basis of the measured gain distribution (FIG. 33D).
(5) The front-end coating film 6 composed of the multi-layer coating film designed in step (4) above is coated on the front-end surface, and the rear-end coating film 7, which is a high-reflectivity film, is coated on the rear-end surface (FIG. 33E).
(6) A terahertz light extraction surface 8 is formed by polishing the front-end surface side of the quantum cascade laser device such that terahertz waves can be extracted (FIG. 33F).
(7) Divide the cleavage bar into individual quantum cascade laser devices 74 (FIG. 33G).
(8) After bonding the quantum cascade laser device 74, the sub-mount 73, and the metal block 72, the device is mounted on a temperature control device 71 such as a Peltier device (FIG. 33H).

In Embodiment 8, polishing for extracting terahertz waves is performed after end surface coating, but polishing may be performed after cleavage.

### Effects of Embodiment 8

As described above, in the method for manufacturing the quantum cascade laser device according to Embodiment 8, the gain distribution of the quantum cascade laser device is measured in advance, the minimum reflectivity is designed on a basis of the measured gain distribution, and then the front-end surface coating film (low-reflectivity film) is coated, thus providing an effect that a quantum cascade laser that can easily achieve terahertz oscillation can be easily manufactured in high yield.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1, 153 n-type first electrode
2 n-type InP substrate
3 n-type InP first cladding layer
4 Fe-doped InP current blocking layer
5 n-type second electrode
6 front-end coating film
7 rear-end coating film
8 terahertz light extraction surface
9 n-type GaInAs first optical confinement layer
10 core region
40, 106, 136 stage
38, 104, 134 active region
39, 105, 135 injector region
11 n-type GaInAs second optical confinement layer
12 n-type InP second cladding layer
13 n-type GaInAs contact layer
21, 23, 25, 27, 29, 31, 35, 37, 81, 83, 85, 87,
89, 91, 93, 99, 101, 103, 111, 113, 115, 117, 119, 121, 123, 125, 131, 133 undoped AlInAs barrier layer
22, 24, 26, 28, 30, 36, 82, 84, 86, 88, 90, 92, 94, 100, 102, 112, 114, 116, 118, 120, 122, 124, 126, 132 undoped GaInAs well layer
32, 34, 96, 98, 128, 130 n-type GaInAs well layer
33, 95, 97, 127, 129 n-type AlInAs barrier layer
42, 212, 231, 241, 249 single-layer coating film
43, 213, 232, 242, 250 first-layer coating film
44, 214, 233, 243, 251 second-layer coating film
45, 215, 234, 244, 252 third-layer coating film
46, 141 coating film
47, 47a, 48a, 142, 222, 222a, 236, 246, 254 dash-dot line
48, 142a, 143, 143a, 223, 223a, 237, 247, 255 double-dash line
49, 49a, 52, 62, 144, 144a, 146, 224, 224a, 238, 248, 256 solid line
50, 50a, 50b, 221, 221a, 221b, 235, 245, 253 dashed line
51, 61, 145 dotted line
41, 74, 211, 500, 600, 700, 800 quantum cascade laser device
71 temperature control device
72 metal block
73 sub-mount
151 semi-insulating InP substrate
152 n-type GaInAs current injection layer
154 Si substrate
161 wafer
162 cleavage bar
163 probe

1. A quantum cascade laser device comprising:
a semiconductor substrate;
a first-conductivity-type first cladding layer formed above the semiconductor substrate;
a core region formed above the first cladding layer and comprising a plurality of stages each having an active region in which a plurality of barrier layers and a plurality of well layers are formed alternately, and an injector region configured to inject electrons into the active region; and
a first-conductivity-type second cladding layer formed above the core region, wherein
a cavity length is L, and
a gain has a maximum gain value at a wavelength λ_{qcl} when current is injected, and
a low-reflectivity film is provided on one end surface such that the reflectivity is minimized at a wavelength λ_{cot} configured to be separated from the wavelength λ_{qcl} by a predetermined wavelength within the wavelength range between two points in which the gain value decreases by a predetermined ratio of the maximum gain value where a wavelength width Δλ_{qcl} is defined as a wavelength width between the two points, and
a wavelength width Δλₘᵢᵣ between two points where the mirror loss value is generated by subtracting a predetermined loss value from the maximum mirror loss value calculated from the reflectivity Rᵣ of the other end surface and the cavity length L is set such that the wavelength width Δλₘᵢᵣ is smaller than the wavelength width Δλ_{qcl}.

2. The quantum cascade laser device according to claim 1, wherein
a first-conductivity-type contact layer is provided on the second cladding layer and a first-conductivity-type first electrode is provided on the rear surface side of the semiconductor substrate and a first-conductivity-type second electrode is provided on the contact layer.

3. The quantum cascade laser device according to claim 1, wherein
the semiconductor substrate is a first-conductivity-type semiconductor substrate, a semi-insulating semiconductor substrate, or a silicon substrate.

4. The quantum cascade laser device according to claim 1, wherein
the gain value corresponding to a predetermined ratio is the gain value of 10% of the maximum gain value.

5. The quantum cascade laser device according to claim 1, wherein
the quantum cascade laser device is mounted on a temperature control device.

6. The quantum cascade laser device according to claim 1, wherein
electrons transition between two higher energy levels and one lower energy level within the active region.

7. The quantum cascade laser device according to claim 1, wherein
electrons transition between two higher energy levels and a plurality of lower energy levels within the active region.

8. A method for manufacturing a quantum cascade laser device according to claim 1, the method comprising steps of:
cleaving a wafer after completing a wafer process to form cleavage bars;
obtaining the wavelength corresponding to the maximum gain value and the gain band by driving the cleavage bar and measuring the wavelength dependence of the gain of the quantum cascade laser device;
designing a low-reflectivity film such that the reflectivity is minimized at a wavelength λ_{cot} configured to be separated from a wavelength λ_{qcl} by a predetermined wavelength within the wavelength range between two points in which the gain value decreases by a predetermined ratio of the maximum gain value where the wavelength width Δλ_{qcl} is defined as a wavelength width between the two points; and
depositing the low-reflectivity film on a front-end surface of the quantum cascade laser device.

9. The method for manufacturing a quantum cascade laser device according to claim 8, further comprising steps of:
polishing an end surface of a semiconductor substrate of the quantum cascade laser device; and
separating the cleavage bar into individual quantum cascade laser devices.

10. The method for manufacturing a quantum cascade laser device according to claim 9, further comprising a step of bonding the quantum cascade laser device to a temperature control device through a sub-mount and a metal block.

11. A quantum cascade laser device comprising:
a semiconductor substrate;
a first-conductivity-type first cladding layer formed above the semiconductor substrate;
a core region formed above the first cladding layer and comprising a plurality of stages each having an active region in which a plurality of barrier layers and a plurality of well layers are formed alternately, and an injector region configured to inject electrons into the active region; and
a first-conductivity-type second cladding layer formed above the core region, wherein
a cavity length is L, and
a gain has a maximum gain value at a wavelength λ_{qcl} when current is injected, and
a low-reflectivity film is provided on one end surface such that the reflectivity is minimized at a wavelength λ_{cot} having the same wavelength as the wavelength λ_{qcl} where a wavelength width Δλ_{qcl} is defined as a wavelength width between two points in which the gain value decreases by a predetermined ratio of the maximum gain value, and
a wavelength width Δλₘᵢᵣ between two points where the mirror loss value is generated by subtracting a predetermined loss value from the maximum mirror loss value calculated from the reflectivity Rᵣ of the other end surface and the cavity length L is set such that the wavelength width Δλₘᵢᵣ is smaller than the wavelength width Δλ_{qcl}.

12. The quantum cascade laser device according to claim 2, wherein
the gain value corresponding to a predetermined ratio is the gain value of 10% of the maximum gain value.

13. The quantum cascade laser device according to claim 3, wherein
the gain value corresponding to a predetermined ratio is the gain value of 10% of the maximum gain value.

14. The quantum cascade laser device according to claim 11, wherein
the gain value corresponding to a predetermined ratio is the gain value of 10% of the maximum gain value.
